(19) United States
(12) Patent Application Publication
(10) Pub. No.: US 2022/0128696 A1
(43) Pub. Date: Apr. 28, 2022

(54) THREE-DIMENSIONAL SENSING SYSTEM

(71) Applicants: ROHM CO., LTD., Kyoto (JP); KYOTO UNIVERSITY, Kyoto (JP)

(72) Inventors: Susumu NODA, Kyoto-shi (JP); Takuya KUSHIMOTO, Kyoto-shi (JP); Menaka DE ZOYSA, Kyoto-shi (JP); Yoshinori TANAKA, Kyoto-shi (JP); Kenji ISHIZAKI, Kyoto-shi (JP); Eiji MIYAI, Kyoto (JP); Wataru KUNISHI, Kyoto (JP)

(73) Assignees: ROHM CO., LTD., Kyoto (JP); KYOTO UNIVERSITY, Kyoto (JP)

(21) Appl. No.: 17/569,922

(22) Filed: Jan. 6, 2022

Related U.S. Application Data
(63) Continuation of application No. PCT/JP2020/027059, filed on Jul. 10, 2020.

(30) Foreign Application Priority Data
Jul. 11, 2019 (JP) 2019-129075
Mar. 30, 2020 (JP) 2020-059842

(51) Int. Cl. G01S 17/894; G01S 7/4865; G01S 7/48; G01S 7/484

(52) U.S. Cl. CPC G01S 17/894; G01S 7/484; G01S 7/4808; G01S 7/4865

(57) ABSTRACT

The 3D sensing system includes: a PC laser array in which PC laser elements are arranged on a plane; a control unit configured to control an operation mode of a laser light source; a driving unit configured to execute a drive control of the PC laser array in accordance with an operation mode controlled by the control unit; a light receiving unit configured to receive reflected light that is laser light emitted from the PC laser array and reflected from a measuring object; a signal processing unit configured to execute signal processing of the reflected light received by the light receiving unit in accordance with the operation mode; and a distance calculation unit configure to execute calculation processing of a distance to the measuring object with respect to a signal processed by the signal processing unit, in accordance with the operation mode, and to output distance data.

### CROSS REFERENCE TO RELATED APPLICATIONS

This is a continuation application (CA) of PCT Application No. PCT/JP2020/027059, filed on Jul. 10, 2020, which claims priority to Japan Patent Application Nos. P2019-129075 filed on Jul. 11, 2019, and P2020-059842 filed on Mar. 30, 2020 and is based upon and claims the benefit of priority from prior Japanese Patent Application Nos. P2019-129075 filed on Jul. 11, 2019, and P2020-059842 filed on Mar. 30, 2020 and PCT Application No. PCT/JP2020/027059, filed on Jul. 10, 2020, the entire contents of each of which are incorporated herein by reference.

### FIELD

The embodiments described herein relate to a three-dimensional (3D) sensing system.

### BACKGROUND

There have been proposed radar devices configured to detect a distance to a measuring object and a shape thereof which exists around a vehicle or the like.

For example, conventional radar devices using a Light Detection and Ranging (LiDAR) method have problems in size, weight, accuracy, reliability, service life, and the like, due to the mechanical moving parts involved in beam scanning. In particular, when mounted on a vehicle, it is difficult to achieve all requirements at the same time, since not only accuracy, reliability, and life, but also strict restrictions on size and weight are often imposed due to a space available for being mounted.

In addition to driving and controlling a laser light source, a driving circuit for a beam scanning and a control circuit thereof are also required. In some cases, mechanisms and circuits are also required for monitoring an emitting direction of beam.

Since a beam emitted from a laser light source has a certain angle of spread, a certain condensing optical system such as a lens is required before the beam is incident onto a beam scanning portion, and the size, weight, and mounting accuracy thereof are problems.

In a simple raster-based operation, beam arrival time density at both ends of a scanning portion is high, and therefore time density in a center portion, where interest level of sensing is high, is reduced. Furthermore, although it would be desirable that a detection region can be changed in accordance with a moving situation or environment, and thereby only the region can be scanned or a plurality of regions simultaneously can be scanned, it is difficult to cope with it by a simple beam scanning technology.

A so-called a Flash Lidar method for calculating the distance for each pixel by emitting pulsed illumination light towards the entire sensing space and receiving reflected light therefrom by an image sensor is also promising as a sensing method, but it cannot handle long distances such as those required for sensing during automatic driving, for example. The structured light method using a light pattern projection is also unsuitable for sensing at long distances. Although it is common in that a light source and an imaging device are used by each thereof, but cannot be shared since requirements for the light source are different from each other.

Each method has its own advantages and disadvantages, and it is practical to choose an appropriate method in accordance with the situation.

On the other hand, photonic crystal (PC) surface emitting lasers (SELs) have been proposed as a next-generation semiconductor laser light source.

### SUMMARY

The embodiments provide a 3D sensing system, having higher accuracy, higher output, miniaturization, and robustness, as well as higher adaptability to sensing regions and sensing objects, and capable of supporting a plurality of sensing modes.

According to one aspect of the embodiments, there is provided a three-dimensional sensing system comprising: a photonic crystal laser array in which a photonic crystal laser element is arranged on a plane; a control unit configured to control an operation mode of a laser light source; a driving unit configured to execute a drive control of the photonic crystal laser array in accordance with the operation mode controlled by the control unit; a light receiving unit configured to receive reflected light that is laser light emitted from the photonic crystal laser array reflected from a measuring object; a signal processing unit configured to execute signal processing of the reflected light received by the signal receiving unit in accordance with the operation mode; and a distance calculation unit configured to execute calculation processing of a distance to the measuring object with respect to a signal processed by the signal processing unit, in accordance with the operation mode, and to output a calculation result as distance data.

According to another aspect of the embodiments, there is provided a three-dimensional sensing system comprising: a signal transmitting unit comprising a two-dimensional photonic crystal surface emitting laser cell array configured to emit laser light to a measuring object; a signal receiving unit comprising an optical system and an image sensor configured to receive reflected light emitted from the signal transmitting unit and reflected from the measuring object; a control unit configured to control an operation mode of a light source of the laser light; transmission direction recognition unit configured to recognize an emitting direction of the laser light emitted from the two-dimensional photonic crystal surface emitting laser cell array; a two-dimensional photonic crystal cell array driving unit configured to execute a drive control of the two-dimensional photonic crystal surface emitting laser cell array on the basis of the emitting direction of the laser light recognized by the transmission direction recognition unit, in accordance with the operation mode; and a signal processing unit comprising a distance detection unit configured to calculate a distance to the measuring object on the basis of a light receiving position on an imaging surface of the image sensor and a time from light emission to light reception in accordance with the operation mode.

According to still another aspect of the embodiments, there is provided a three-dimensional sensing system comprising: a flash light source configured to emit laser light to an entire surface of a specific region; a two-dimensional photonic crystal surface emitting laser cell array configured to emit the laser light to a target region of the specific region; a control unit configured to control an operation mode of a laser light source; a flash driving unit configured to execute a drive control of the flash light source and a two-dimensional photonic crystal cell array driving unit configured to execute a drive control of the two-dimensional photonic crystal surface emitting laser cell array, in accordance with the operation mode controlled by the control unit; a signal receiving unit configured to receive a reflected light that is the laser light emitted from the flash light source and reflected from a measuring object included in the specific region, and to receive a reflected light that is the laser light emitted from the two-dimensional photonic crystal surface emitting laser cell array and reflected from measuring object included in the target region; a signal processing unit configured to execute signal processing of the reflected light received the signal receiving unit in accordance with the operation mode; and a distance detection unit configured to execute calculation processing of the distance to the measuring object with respect to the signal processed by the signal processing unit in accordance with the operation mode, wherein the signal processing unit determines whether or not there is any region where the signal to noise ratio of the reflected light emitted from the flash light source and reflected is lower than the predetermined threshold value in the specific region, wherein if there is a region where the signal to noise ratio is lower than the predetermined threshold value, the signal processing unit controls the two-dimensional photonic crystal cell array driving unit to irradiate only the region where the signal to noise ratio is lower than the predetermined threshold value as a target with spot laser light from the two-dimensional photonic crystal surface emitting laser cell array.

According to the embodiments, there can be provided the 3D sensing system, having higher accuracy, higher output, miniaturization, and robustness, as well as higher adaptability to sensing regions and sensing objects, and capable of supporting a plurality of sensing modes.

### BRIEF DESCRIPTION OF DRAWINGS

FIG. 1 is a schematic bird's-eye view configuration diagram of a two-dimensional photonic crystal (2D-PC) surface emitting laser (SEL) cell applicable to a 3D sensing system according to the embodiments.

FIG. 2 is a schematic bird's-eye view configuration diagram of the 2D-PC SEL cell applicable to the 3D sensing system according to the embodiments, configured including a transparent electrode or a DBR layer which passes through a feedback laser light C (FB) at a back side surface thereof.

In the 2D-PC SEL cell applicable to the 3D sensing system according to the embodiments, FIG. 3A is a top view diagram illustrating a state where a lattice 212A for forming optical resonance state is arranged as a lattice point where a hole (different refractive index region) is arranged at a 2D-PC layer; FIG. 3B is a top view diagram illustrating a state where a lattice 212B for light-emitting is arranged; FIG. 3C is a top view diagram illustrating a state where the lattice 212A for forming optical resonance state and the lattice 212B for light-emitting are arranged; and FIG. 3D is a top view diagram illustrating a state where a hole 211 is arranged.

In the 2D-PC SEL cell applicable to the 3D sensing system according to the embodiments, FIG. 4A is a schematic diagram of emitting lights A and emitting light B; and FIG. 4B is a schematic diagram for explaining an aspect that the emitting lights A and emitting light B existing on the same plane are rotated.

In the 2D-PC SEL cell applicable to the 3D sensing system according to the embodiments, FIG. 5A is a top view diagram illustrating a state where a lattice 212A for forming optical resonance state composed of square lattice is arranged as a lattice point where a hole (different refractive index region) is arranged at a 2D-PC layer; FIG. 5B is a top view diagram illustrating a state where a lattice 212B for light-emitting composed of orthorhombic lattice is arranged; and FIG. 5C is a top view diagram illustrating a state where the lattice 212A for forming optical resonance state and the lattice 212B for light-emitting are arranged.

In the 2D-PC SEL cell applicable to the 3D sensing system according to the embodiments, FIG. 6A is a schematic diagram of output characteristics illustrating a relationship between laser light intensity L an injection current I of the emitting light A and emitting light B and; and FIG. 6B is a schematic configuration diagram of a configuration of including a transparent electrode (or DBR layer) configured to pass through a feedback laser light C (FB), and a photo diode (PD) 118PD configured to detects laser light C (FB), at the back side surface thereof.

FIG. 7 is a schematic block configuration diagram for explains a feedback control mechanism formed by combining a 2D-PC SEL cell array and a two-dimensional photo diode (2D-PD) cell array, in the 3D sensing system according to the embodiments.

FIG. 8 is a schematic configuration diagram for explaining a feedback control mechanism formed by laminating and combining the 2D-PC SEL cell array and the 2D-PD cell array via a transparent electrode, in a 3D sensing system according to the embodiments.

FIG. 9 is a schematic plane configuration diagram of the 2D-PC SEL cell array applicable to the 3D sensing system according to the embodiments.

FIG. 10 is a schematic plane configuration diagram of the 2D-PD cell array applicable to the 3D sensing system according to the embodiments.

FIG. 11 is a schematic block configuration diagram for explaining an overview of the 3D sensing system according to the embodiments.

FIG. 12 is an operational flowchart for explaining a distance calculation procedure for three operation modes, in the 3D sensing system according to the embodiments.

FIG. 13 is an operational flowchart for explaining the three operation modes, in the 3D sensing system according to the embodiments.

In the LiDAR operation mode executed in the 3D sensing system according to the embodiments, FIG. 14A is a schematic diagram for explaining an operational principle of detecting reflected light RA and reflected light RB respectively corresponding to the emitted light A and emitted light B by an image sensor; and FIG. 14B is a conceptual diagram of the image sensor configured to detect the reflected light RA and reflected light RB.

In a flash LiDAR operation mode executed in the 3D sensing system according to the embodiments, FIG. 15A is a schematic diagram for explaining an operational principle of detecting reflected light RFL corresponding to emitted light FL by the image sensor; and FIG. 15B is a conceptual diagram of the image sensor configured to detect the reflected light RFL.

In a light-section method operation mode executed in the 3D sensing system according to the embodiments, FIG. 16A is a schematic diagram for explaining an operational principle of detecting reflected light RST corresponding to rotating stripe-shaped emitted light ST by the image sensor; and FIG. 16B is a conceptual diagram of the image sensor configured to detect the reflected light RST.

FIG. 17 is a diagram for explaining details of an operation of detecting the reflected light RST corresponding to the rotating stripe-shaped emitted light ST by the image sensor, in the light-section method operation mode executed in the 3D sensing system according to the embodiments.

FIG. 18 is a flow chart of the LiDAR operation mode, in the 3D sensing system according to the embodiments.

FIG. 19 is a flow chart of the flash LiDAR operation mode, in the 3D sensing system according to the embodiments.

FIG. 20 is a flow chart of the light-section method operation mode, in the 3D sensing system according to the embodiments.

FIG. 21A is a schematic block configuration diagram of the 3D sensing system according to the embodiments.

FIG. 21B is an alternative schematic block configuration diagram of the 3D sensing system according to the embodiments.

FIG. 22A is a schematic block configuration diagram of a 3D sensing system according to a modified example 1 of the embodiments.

FIG. 22B is an alternative schematic block configuration diagram of the 3D sensing system according to the modified example 1 of the embodiments.

FIG. 23 is a schematic block configuration diagram of a 2D-PC cell array driving unit applicable to the 3D sensing system according to the embodiments.

FIG. 24A is a schematic block configuration diagram of a 3D sensing system according to a modified example 2 of the embodiments.

FIG. 24B is an alternative schematic block configuration diagram of the 3D sensing system according to the modified example 2 of the embodiments.

FIG. 25 is a schematic block configuration diagram of a 3D sensing system according to a modified example 3 of the embodiments, as a time-of-flight (TOF) ranging system.

FIG. 26 is a schematic block configuration diagram of an image sensor (area) applicable to the 3D sensing system according to the embodiments.

FIG. 27A is a schematic diagram of an example of arrangement of a twin beam emitted from the 2D-PC SEL cell array applicable to the 3D sensing system according to the embodiments; and FIG. 27B is a schematic enlarged drawing of a central beam and a beam adjacent thereto.

FIG. 28 is a schematic diagram of an example of twin beam arrangement emitted from the 2D-PC SEL cell array applicable to a 3D sensing system according to the embodiments, in particular an example of a beam arrangement using a closest-packing pattern of circles.

In an example of the twin beam using the closest-packing pattern of circles emitted from the 2D-PC SEL cell array applicable to the 3D sensing system according to the embodiments, FIG. 29A is an explanatory diagram of the maximum horizontal angle MHD and the maximum vertical angle MVD in a part of a spherical surface showing a sensing range; FIG. 29B is an explanatory diagram showing a beam divergence angle BDA and a center position of the beam of equilateral triangle arrangement; and FIG. 29C is an example of arrangement of the laser beam.

In the 3D sensing system according to the embodiments, FIG. 30A is a schematic diagram of a light receiving system (16, 18) configured to receive reflected light R; and FIG. 30B is a schematic diagram of the image sensor illustrated in FIG. 30A.

As schematic diagrams for explaining an example in which differences occur in light intensity in accordance with a direction (position) even if the equal current value is injected into each cell of the 2D-PC SEL cell array, in the 3D sensing system according to a comparative example, FIG. 31A is a diagram illustrating an aspect of radiation of a beam BM when the equal current value I is injected into each cell 121, 122, 123, 124; FIG. 31B is a diagram illustrating an aspect of Far Field Pattern (FFP) when the beam BM radiation angle θ=0 degree; FIG. 31C is a diagram illustrating an aspect of FFP when θ=20 degrees; FIG. 31D is a diagram illustrating an aspect of FFP when θ=40 degrees; and FIG. 31E is a diagram illustrating an aspect of FFP when θ=60 degrees.

As schematic diagrams for explaining an example in which the light intensity is uniformed in accordance with the direction (position) by injecting a different current value for each position into each cell of the 2D-PC SEL cell array, in the 3D sensing system according to the embodiments, FIG. 32A is a diagram illustrating an aspect of radiation of the beam BM when injecting different current values I1, I2, I3, and I4 respectively into the cells 121, 122, 123, and 124; FIG. 32B is a diagram illustrating an aspect of FFP when the beam BM radiation angle θ=0 degree; FIG. 32C is a diagram illustrating an aspect of FFP when θ=20 degrees; FIG. 32D is a diagram illustrating an aspect of FFP when θ=40 degrees; and FIG. 32E is a diagram illustrating an aspect of FFP when θ=60 degrees.

In an example of emitting beam control of the 2D-PC SEL cell array applicable to the 3D sensing system according to the embodiments, FIG. 33A is a top view diagram illustrating a state where a lattice 212A for forming optical resonance state and a lattice 212B for light-emitting are arranged in one cell; FIG. 33B is a schematic top view diagram of one cell; and FIG. 33C is a structural example of an electrode arrangement for realizing uniaxial scanning.

In an example of emitting beam control of the 2D-PC SEL cell array applicable to the 3D sensing system according to the embodiments, FIG. 34A is a diagram illustrating a relationship between parameters r₁, r₂ indicating a position, and the angle θ; and FIG. 34B is an alternative structural example of the electrode arrangement for realizing the uniaxial scanning.

In an example of emitting beam control of the 2D-PC SEL cell array applicable to the 3D sensing system according to the embodiments, FIG. 35A is a structural example of an electrode arrangement for realizing biaxial scanning; and FIG. 35B is a schematic diagram of a scanning direction.

In an example of emitting beam control of the 2D-PC SEL cell array applicable to the 3D sensing system according to the embodiments, FIG. 36A is a structural example of an electrode arrangement for realizing rotational scanning; and FIG. 36B is a schematic diagram of a scanning direction.

In the 2D-PC SEL cell applicable to the 3D sensing system according to the embodiments, FIG. 37A is a top view diagram illustrating a state where a lattice 212A for forming optical resonance state is arranged as a lattice point where a hole (different refractive index region) is arranged at a 2D-PC layer; FIG. 37B is a top view diagram illustrating a state where a lattice 212B for light-emitting is arranged; FIG. 37C is a top view diagram illustrating a state where upper electrodes 252 are arranged; and FIG. 37D is a top view diagram illustrating an alternative state where the upper electrodes 252 are arranged.

FIG. 38 is a conceptual diagram of an operation mode realized by combining the flash operation mode and the LiDAR operation mode, in the 3D sensing system according to the embodiments.

FIG. 39 is an operational flowchart of a flash LiDAR system according to a comparative example.

FIG. 40 is an operational flowchart of the operation mode realized by combining the flash operation mode and the LiDAR operation mode, in the 3D sensing system according to the embodiments.

FIG. 41 is a schematic sectional diagram of an example of an irradiation pattern, as an example of a photonic crystal (PC) laser light source for entire surface irradiation, in the 3D sensing system according to the embodiments.

FIG. 42 is a schematic diagram of an illuminating surface of an example of the irradiation pattern, as an example of the PC laser light source for entire surface irradiation, in the 3D sensing system according to the embodiments.

FIG. 43A is a schematic block configuration diagram of the operation mode realized by combining the flash operation mode and the LiDAR operation mode, in the 3D sensing system according to the embodiments.

FIG. 43B is an alternative schematic block configuration diagram of the operation mode realized by combining the flash operation mode and the LiDAR operation mode, in the 3D sensing system according to the embodiments.

FIG. 44A is a schematic block configuration diagram of the operation mode realized by combining the flash operation mode and the LiDAR operation mode, in a 3D sensing system according to a modified example 4 of the embodiments.

FIG. 44B is an alternative schematic block configuration diagram of the operation mode realized by combining the flash operation mode and the LiDAR operation mode, in the 3D sensing system according to the modified example 4 of the embodiments.

FIG. 45 is a schematic block configuration diagram of a 2D-PC cell array driving unit and a flash light source driving unit (FL driving unit), applicable to the operation mode realized by combining the flash operation mode and the LiDAR operation mode, in the 3D sensing system according to the embodiments.

FIG. 46A is a schematic block configuration diagram of the operation mode realized by combining the flash operation mode and the LiDAR operation mode, in a 3D sensing system according to a modified example 5 of the embodiments.

FIG. 46B is an alternative schematic block configuration diagram of the operation mode realized by combining the flash operation mode and the LiDAR operation mode, in the 3D sensing system according to the modified example 5 of the embodiments.

FIG. 47 is a schematic block configuration diagram of a time-of-flight (TOF) ranging system in the operation mode realized by combining the flash operation mode and the LiDAR operation mode, in a 3D sensing system according to a modified example 6 of the embodiments.

### DESCRIPTION OF EMBODIMENTS

There will now be described embodiments with reference to the drawings. In the description of the following drawings to be explained, the identical or similar reference sign is attached to the identical or similar part. However, it should be noted that the drawings are schematic and the relation between thickness and the plane size and the ratio of the thickness of each layer differs from an actual thing. Therefore, detailed thickness and size should be determined in consideration of the following explanation. Of course, the part from which the relation and ratio of a mutual size differ also in mutually drawings is included.

Moreover, the embodiments described hereinafter merely exemplify the device and method for materializing the technical idea; and the embodiments do not specify the material, shape, structure, placement, etc. of each component part as the following. The embodiments of the present invention may be changed without departing from the spirit or scope of claims.

### [Embodiments]

The embodiments discloses a 3D sensing system formed by combining a two-dimensional photonic crystal (2D-PC) surface emitting laser (SEL) element and a two-dimensional (2D) arrayed element thereof with an imaging device.

The 3D sensing system according to the embodiments calculates a distance to and a direction of a measuring object by irradiating the measuring object with radiately laser light and receiving a scattered light from the measuring object. Since the photonic crystal has flexible controllability of a laser beam, it can flexibly control a beam direction (emitting direction of the laser light) even if not providing any mechanical operating unit (solid state).

In particular, it becomes possible to realize a light source for 3D sensing which has a plurality of operation modes by utilizing characteristics of the photonic crystal, such as flexible emission control function (time, intensity, direction), higher output, higher quality beam, small size, and robustness (hard to break) and affordable price.

Moreover, it becomes possible to realize a control method of symmetrical emitting beam which is a characteristic of the PC laser (a beam arrangement design method for satisfying a region as a sensing object and an emission pattern control corresponding thereto (including also the case of a single beam emitted in a normal direction of the device)). The 3D sensing system according to the embodiments, by changing operation modes of the laser light source, can configure the following three sensing modes (1) to (3) in one 3D sensing system.
(1) LiDAR: A sensing mode (beam scanning type) in which a laser light is emitted in a certain direction, a reflected light from a measuring object is captured, and thereby a distance to the measuring object is calculated for each beam.
(2) Flash LiDAR: A sensing mode (flash type) in which with a certain region (sensing space) is irradiated with light for given length of time, a scattered light from a measuring object is received by an imaging device, and thereby a distance to the measuring object in the irradiation region is calculated on the basis of a return time for each pixel of the imaging device.
(3) Structured Light Projection: A sensing mode in which a measuring object is irradiated with a certain light pattern, an image of the pattern is matched with an image obtained by an imaging device, and thereby calculating a distance to the measuring object.

The beam scanning type LiDAR scans the beam (transmitting signal) within a range of detecting the measuring object, captures the scattered reflected light (reflected signal) from the measuring object, calculates the direction by recognizing which direction the light is reflected from, and thereby calculates the distance on the basis of the time until the light to be reflected and returned (Time of Flight (TOF)).

Various technology with regard to a laser radar is an ingenuity for a signal processing logic for calculating the distance and direction, a scan method of the beam corresponding thereto, and a method of a spatial modulation for realizing such scanning. As a means for the spatial modulation, there are methods, such as a polygon mirror, a galvanomirror, and Micro Electro Mechanical Systems (MEMS), a method of arraying the laser light source to be subjected to light control (Vertical Cavity Surface Emitting Laser (VCSEL) etc.), or an optical phased array.

The 3D sensing system according to the embodiments is capable of scanning (e.g., rotational scanning) differently from conventional raster scanning even in the beam scanning type sensing mode. Moreover. the arrayed light-receiving element can also distinguish reflected light from a plurality of laser beams and function also as the flash LiDAR. Also in the flash type sensing mode, it is also possible to sense only a certain region.

Since the emission control function of the 3D sensing system according to the embodiments has a high compatibility (sensing region, cooperative operation of a plurality of systems, learning control) with software control (program control), it can easily support also adaptive sensing that incorporates learning functions, etc. According to such characteristics, it is also possible to easily support applicability of encoding of the emitting beam, a cooperative operation of a plurality of systems, etc.

The 3D sensing system according to the embodiments is a solid-state type system, which is small and is hard to break, and allows for greater flexibility of setting positions. Moreover, it has resistance to noise and interference (utilizing excellent controllability in hardware and software).

Since a light emitting unit of the 3D sensing system according to the embodiments requires no beam scanning mechanism, the size thereof is at a semiconductor package level and no optical system (collimating optical system) for converging the emitting beam is also required. Therefore, it is possible to emit light in any driving condition under independent in flexible directions, and a cooperative operation of a plurality of devices can also be realized. Moreover, since no beam scanning mechanism such as a rotating mirror or MEMS mirror required for the LiDAR applicability is required, a system that is ultra-compact, robust, and can be installed freely can be realized.

### [2D-PC SEL Applicable to 3D Sensing System]

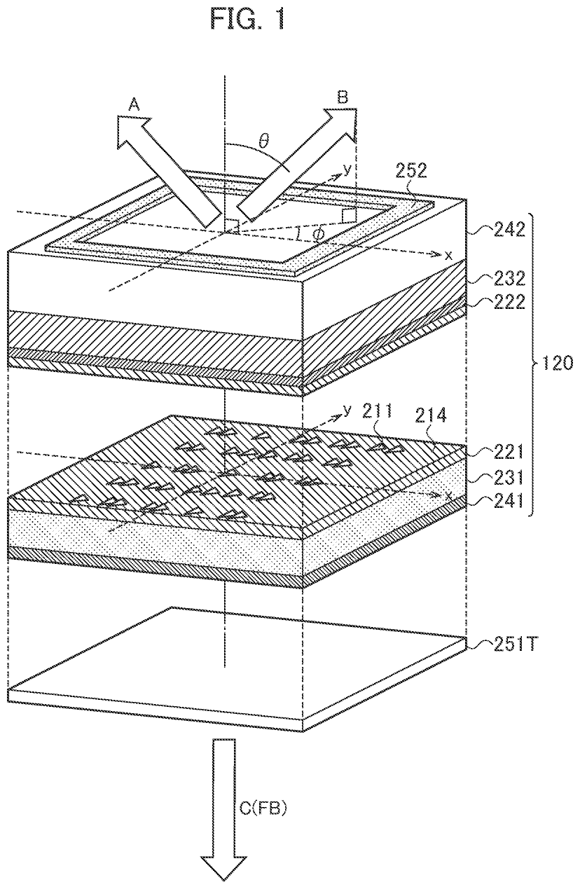

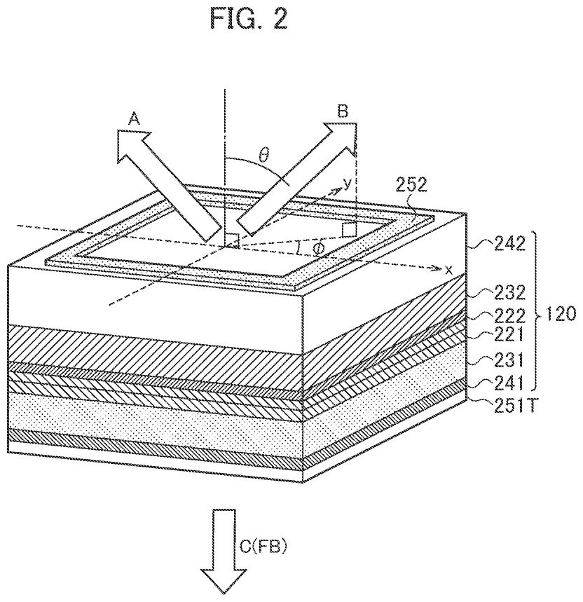

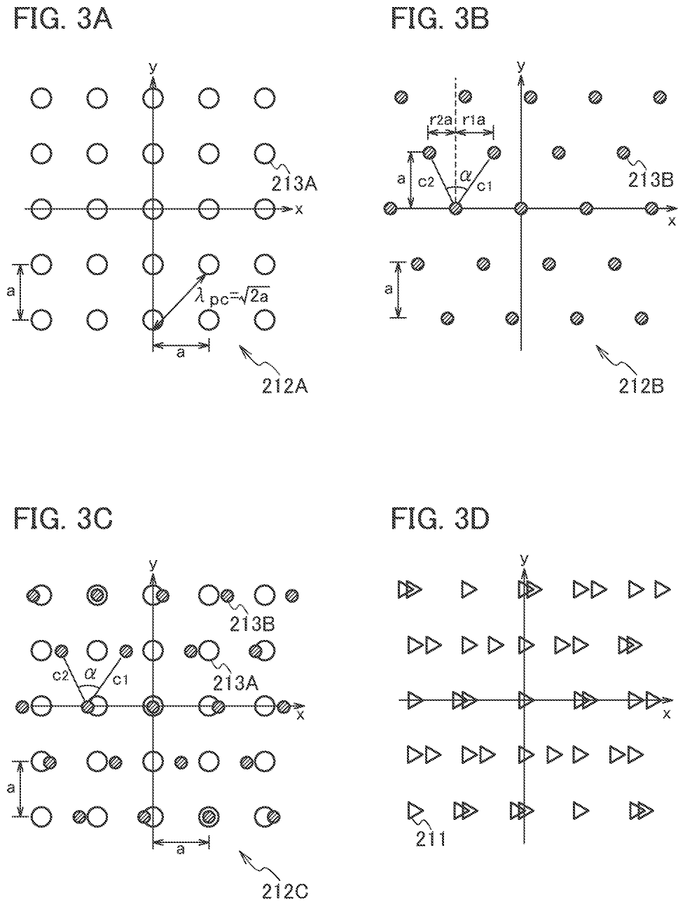

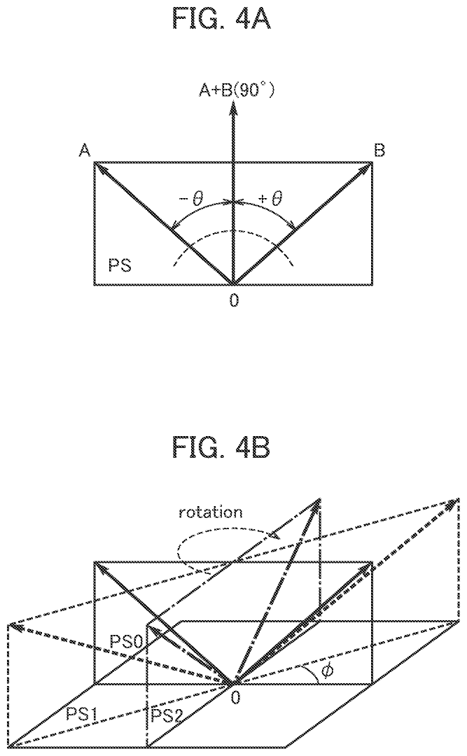

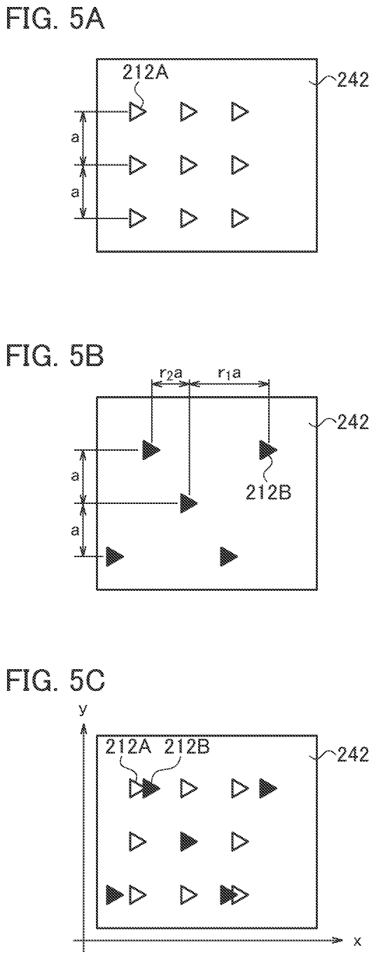

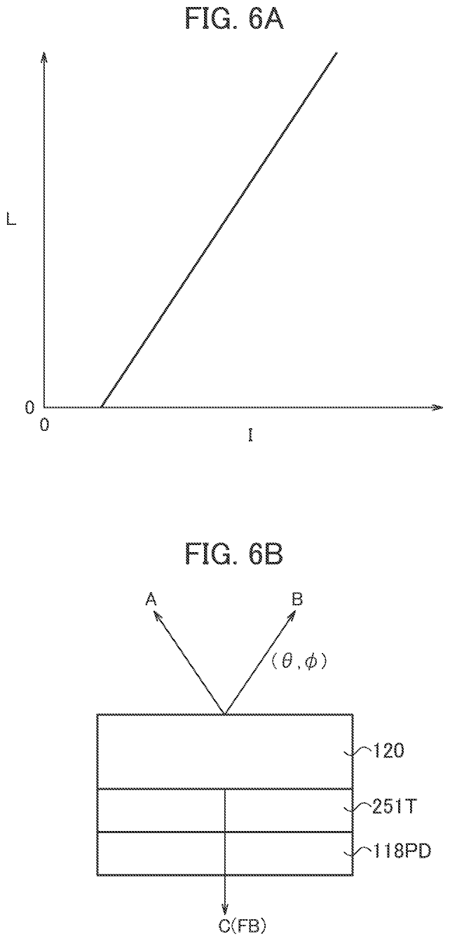

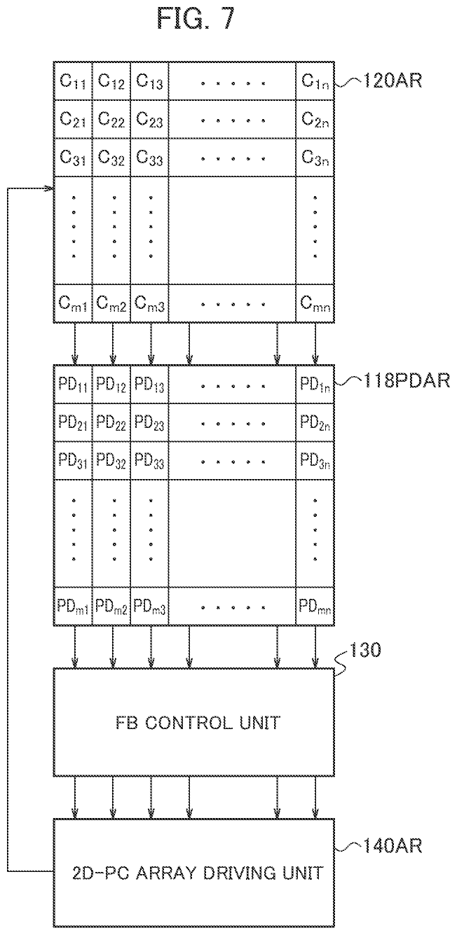

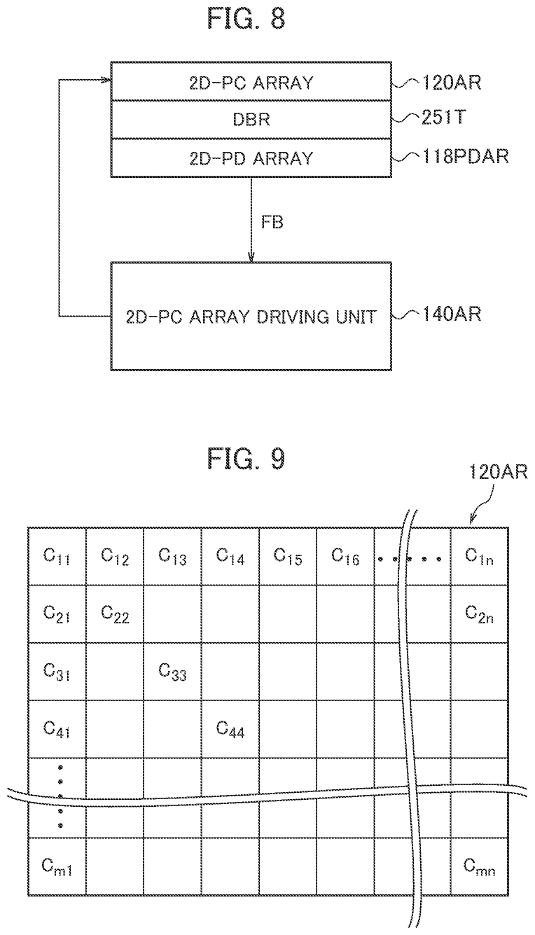

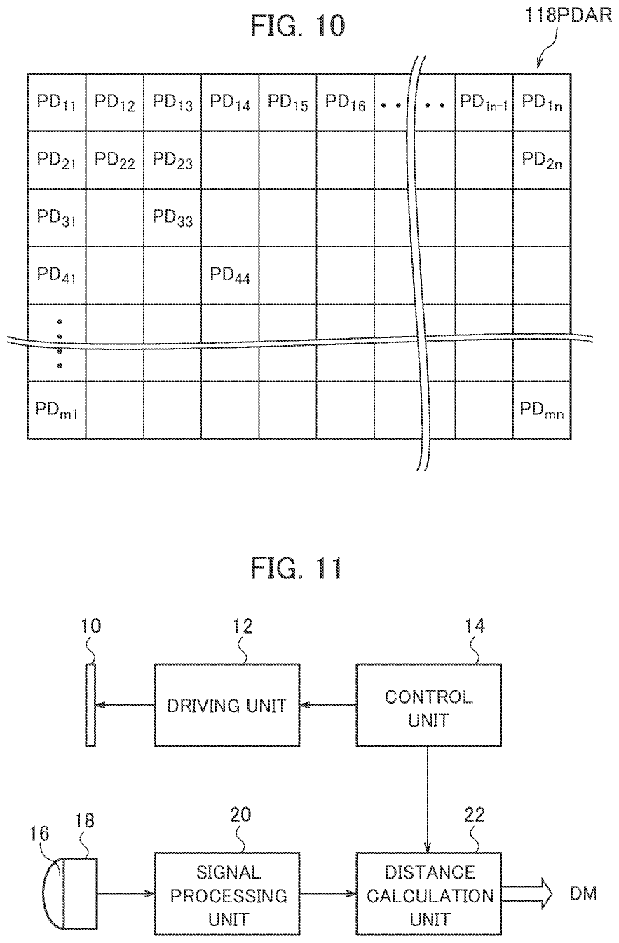

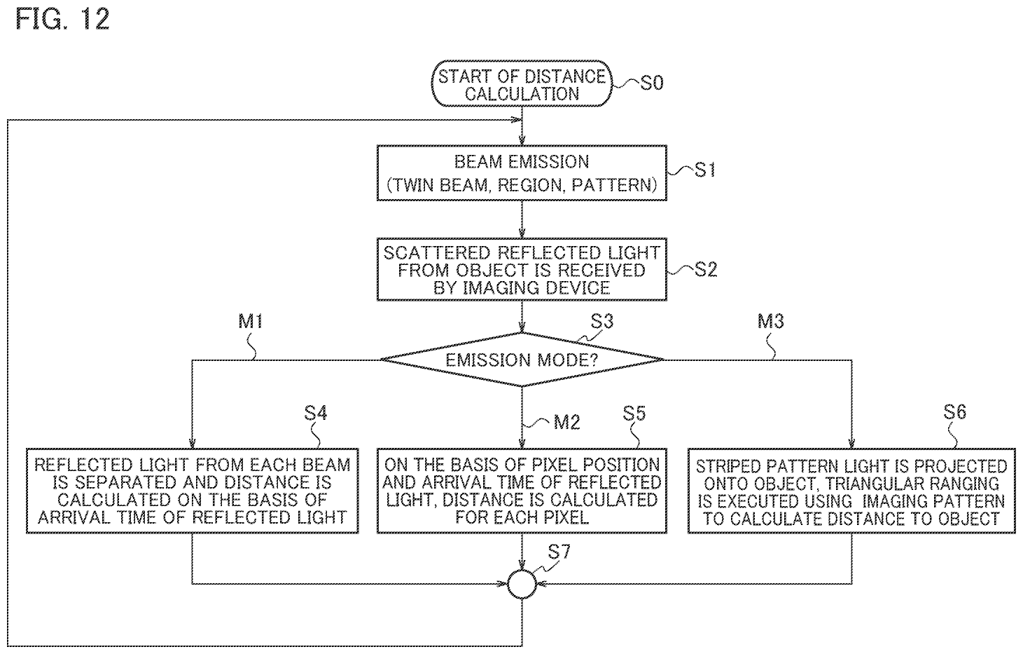

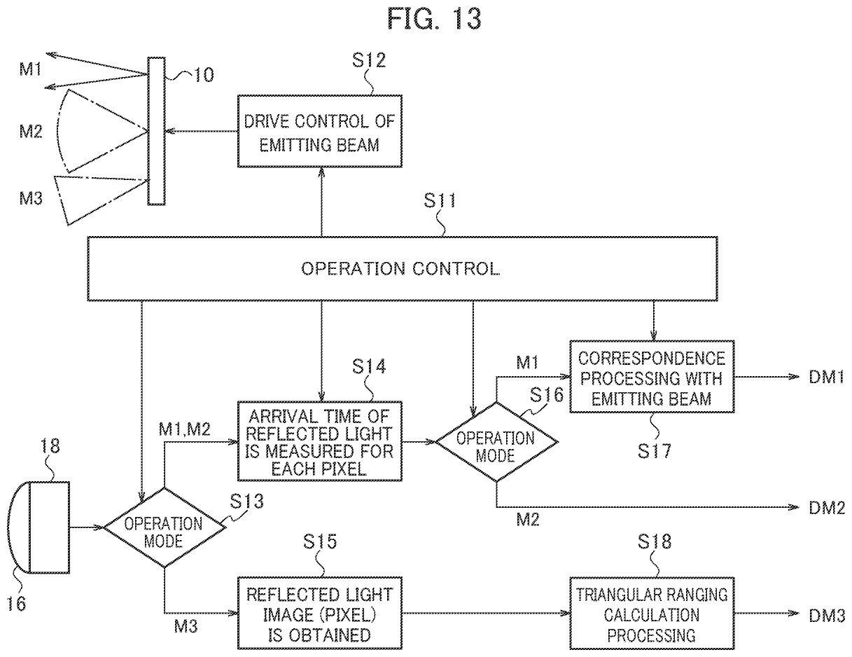

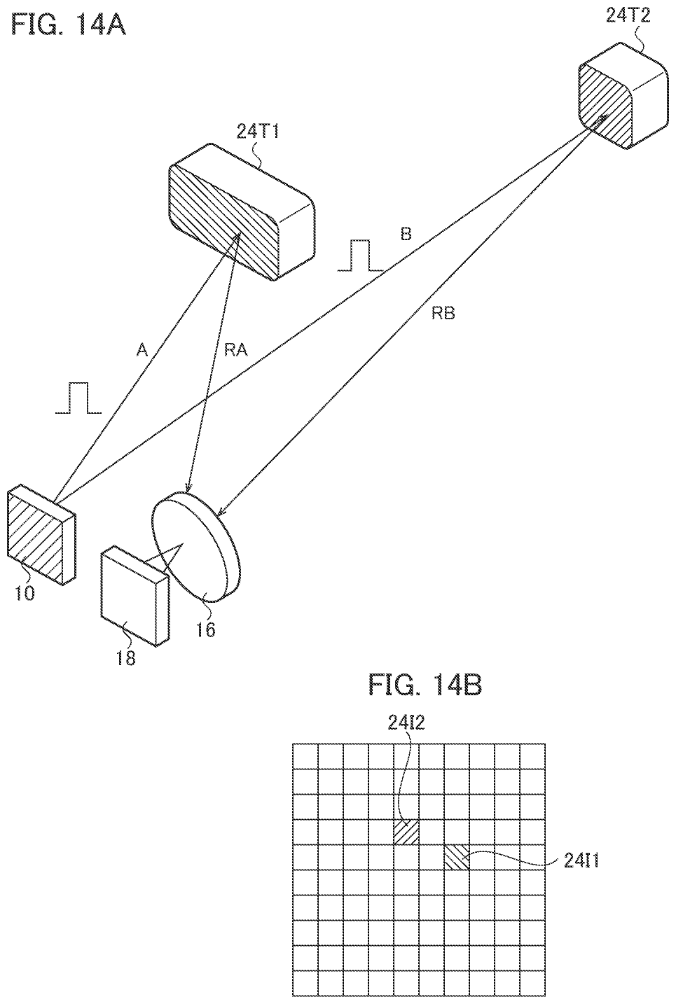

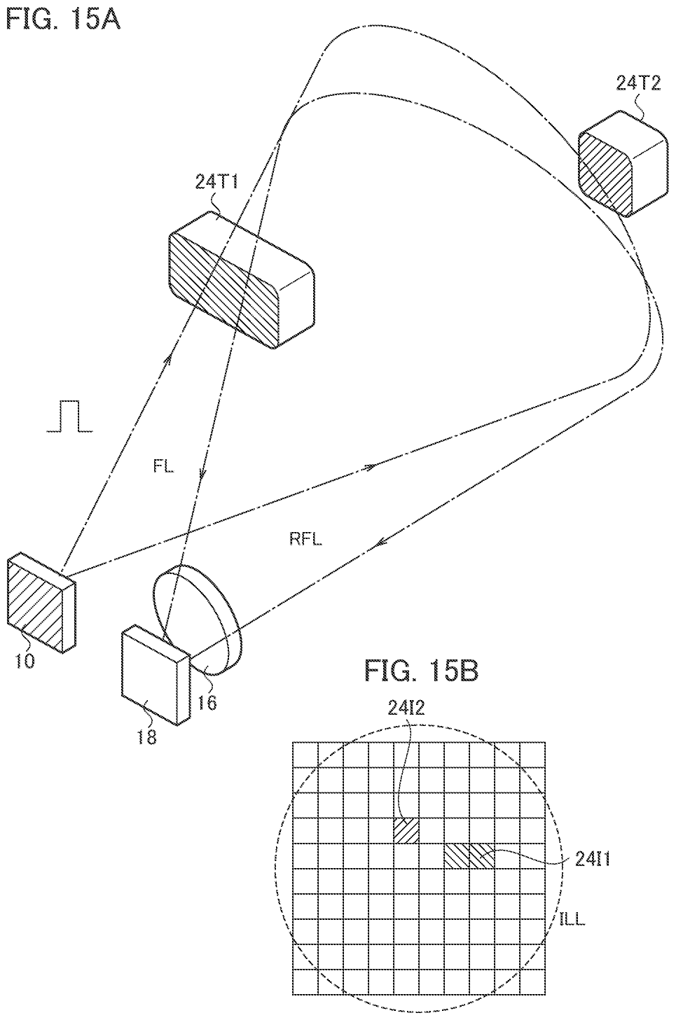

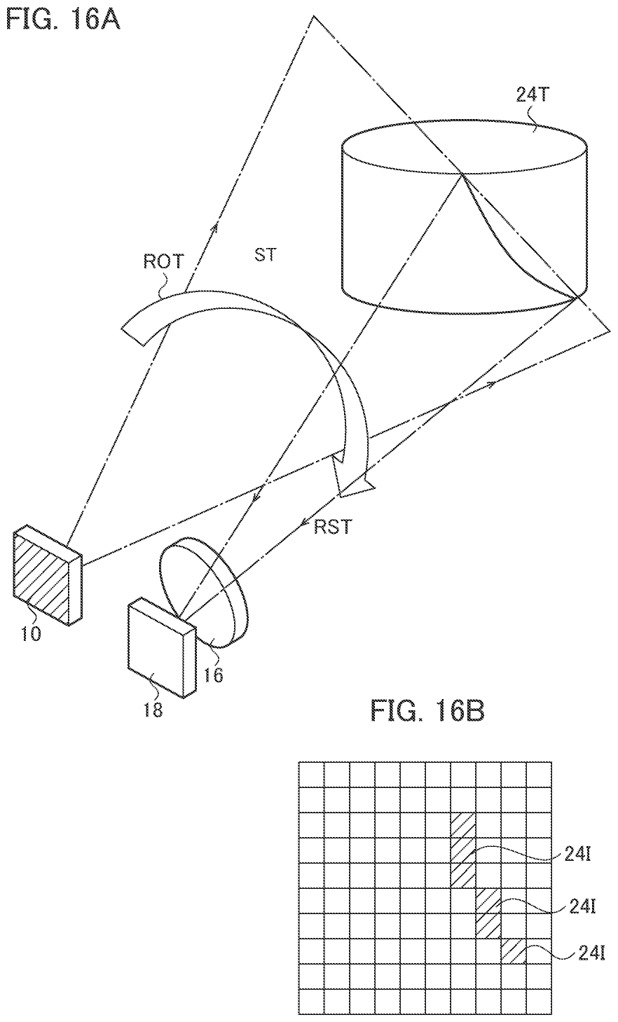

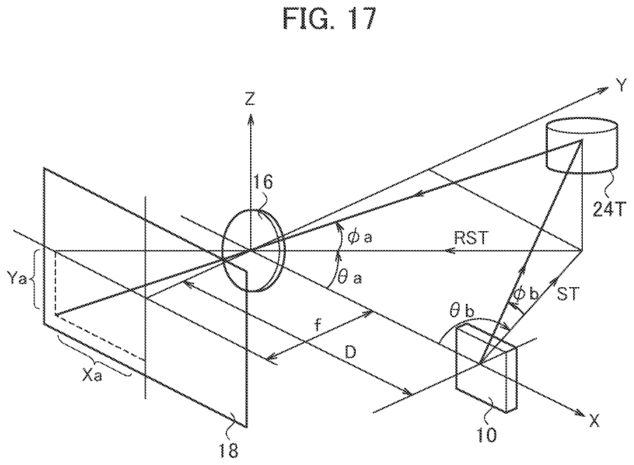

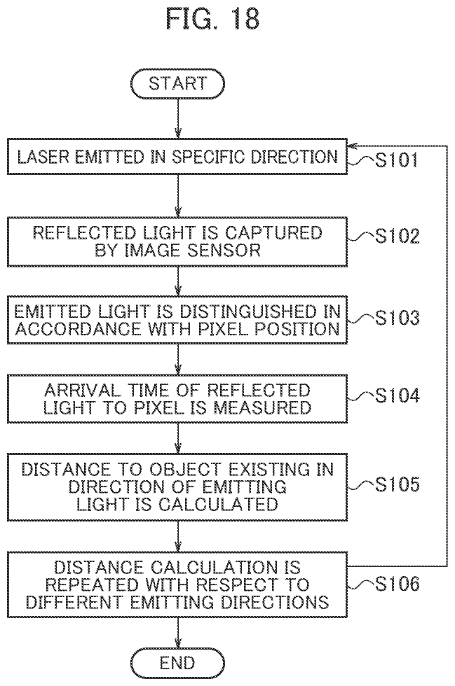

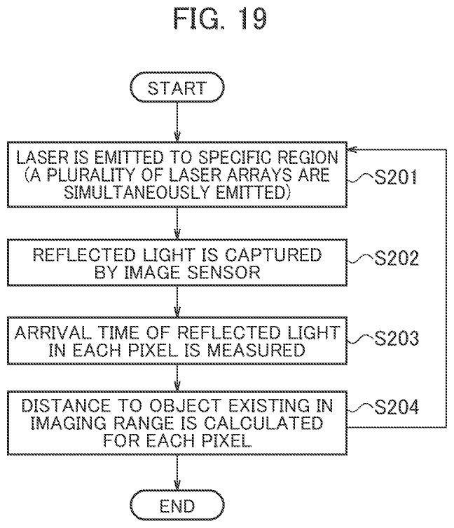

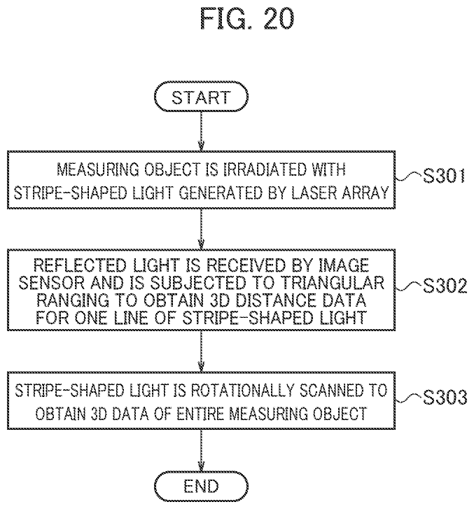

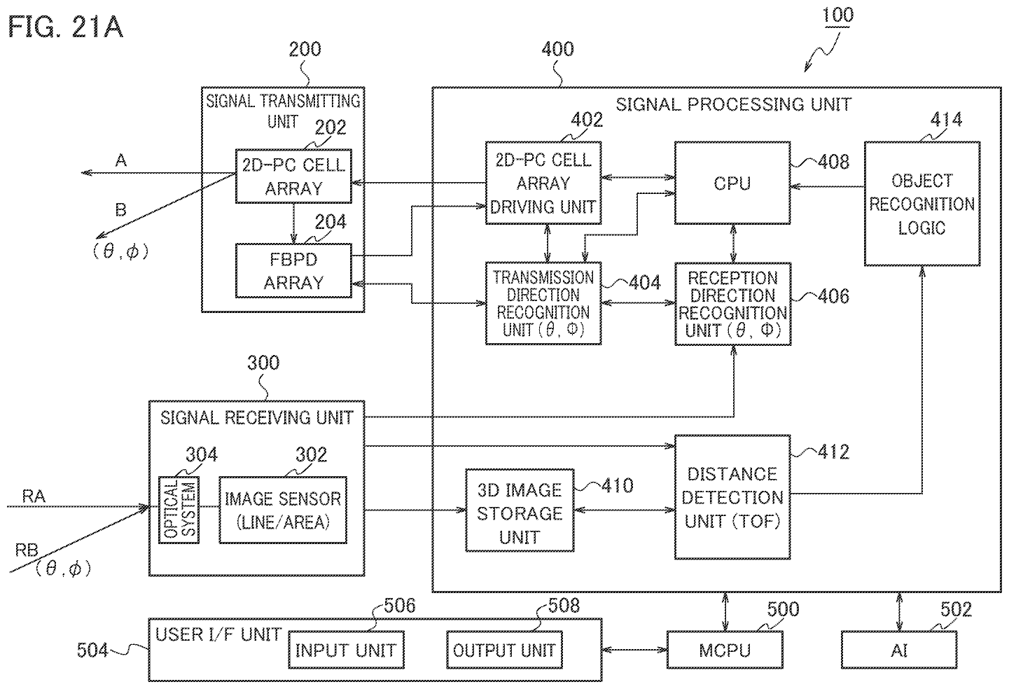

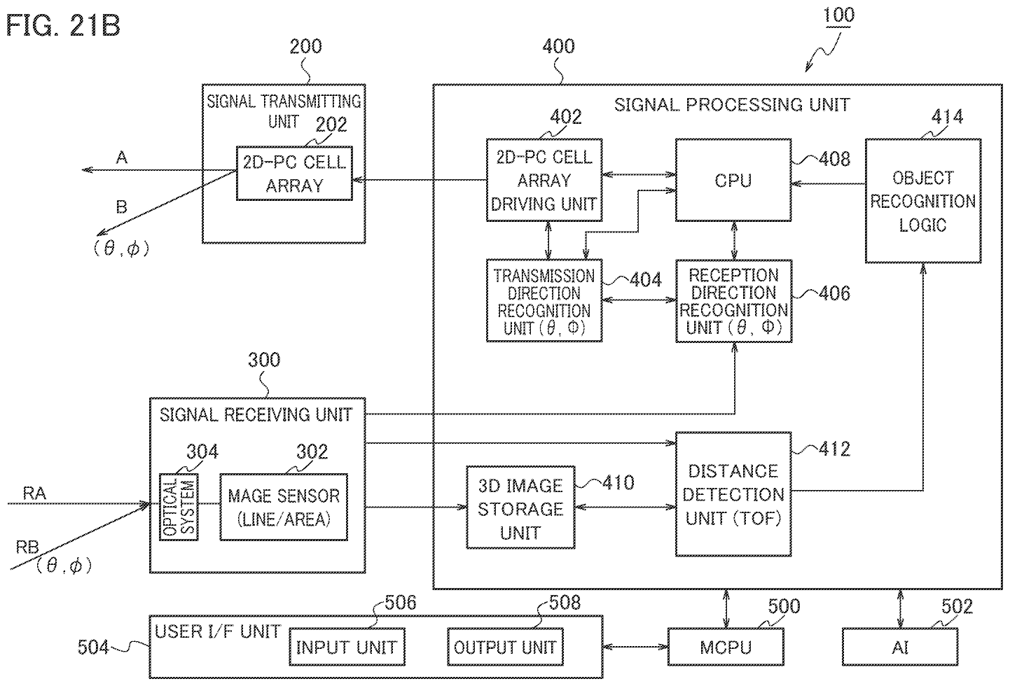

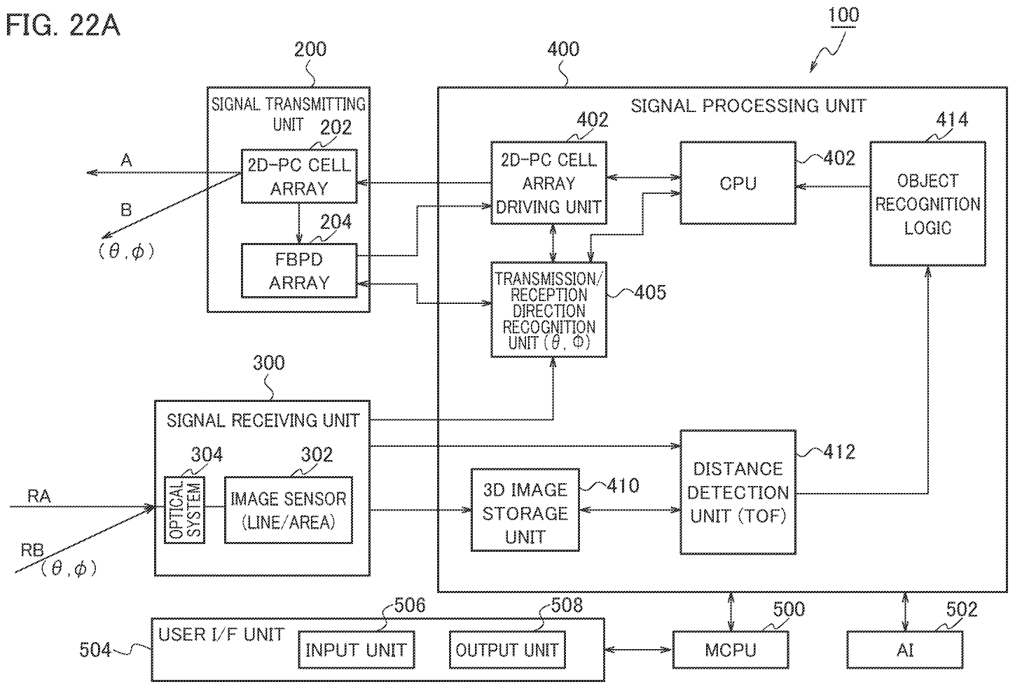

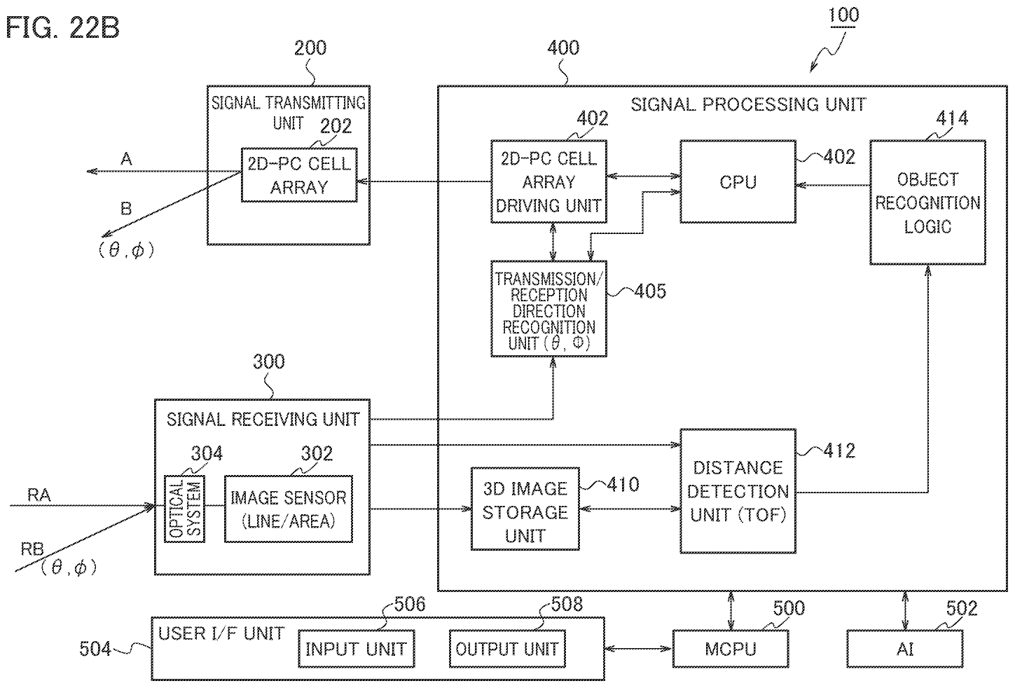

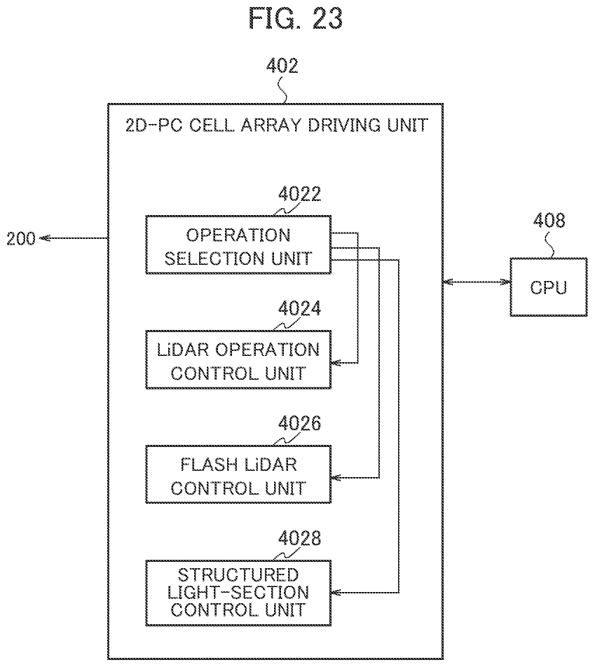

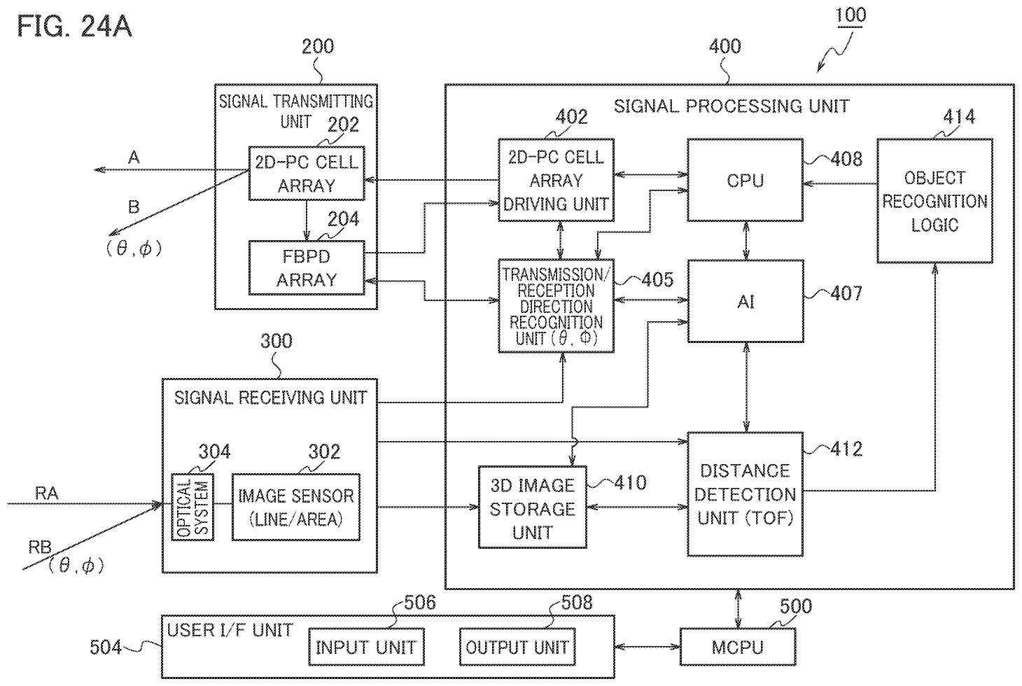

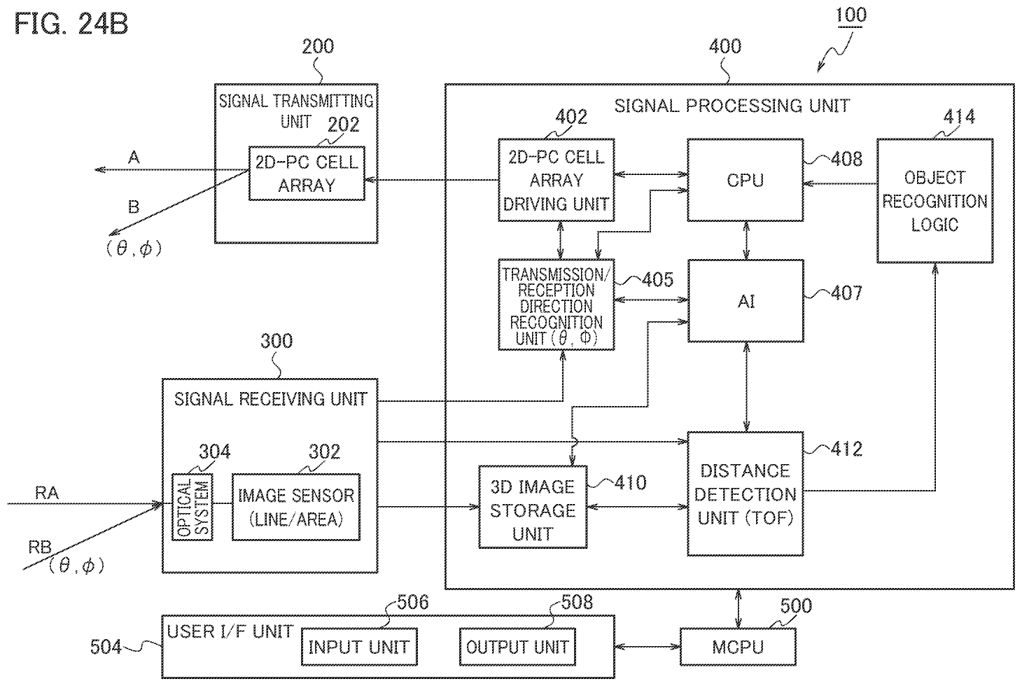

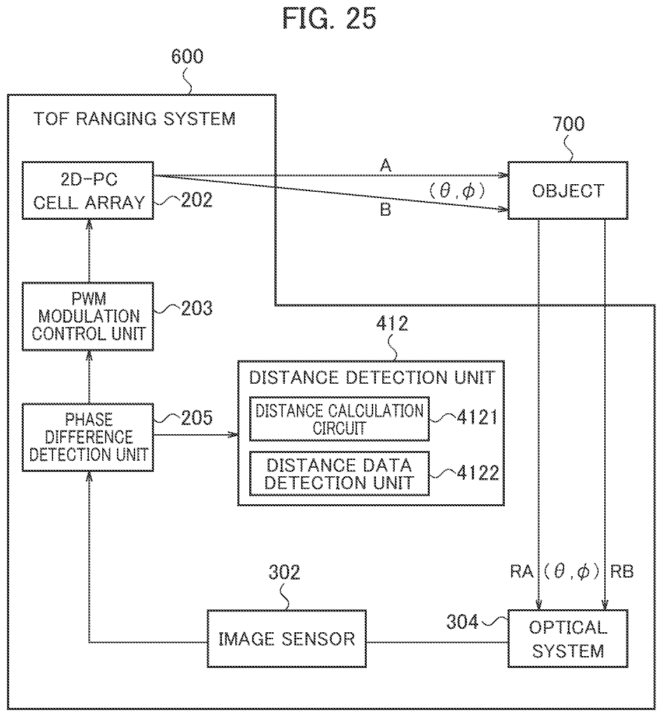

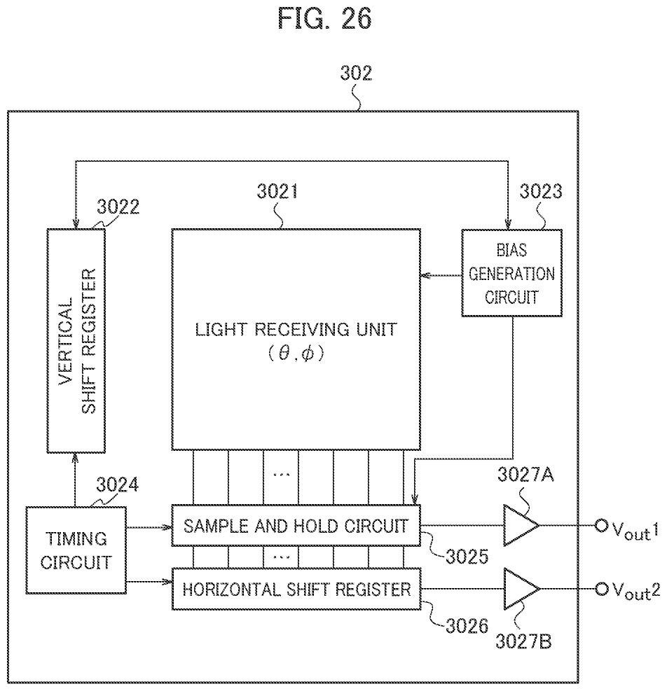

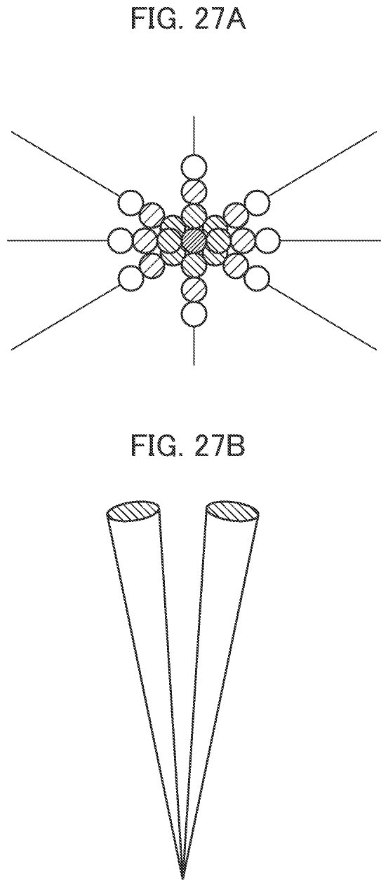

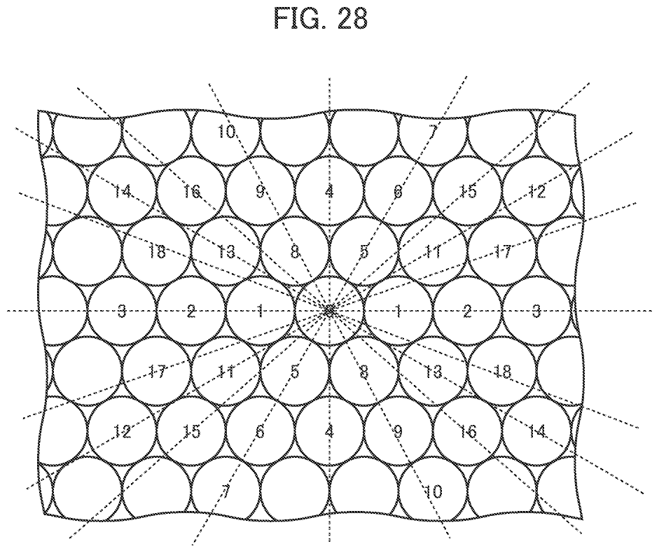

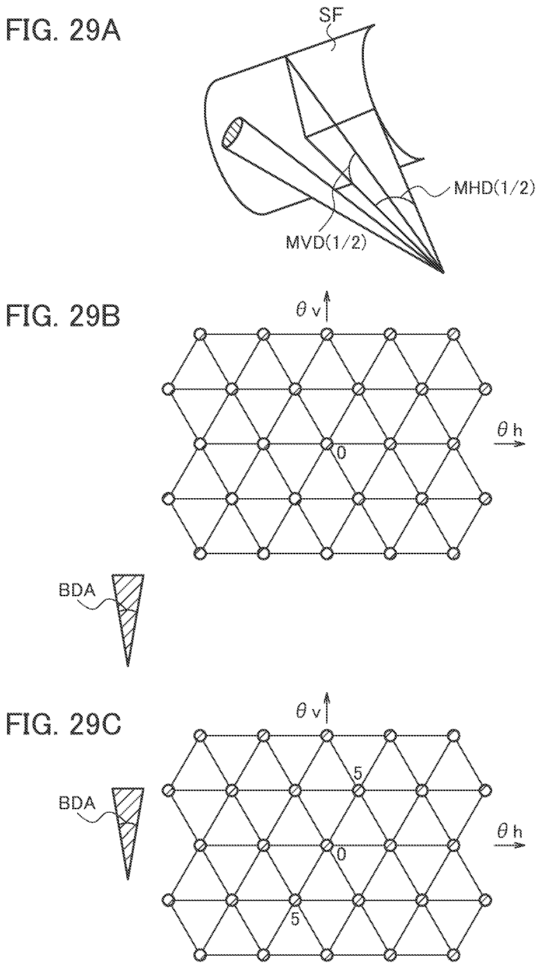

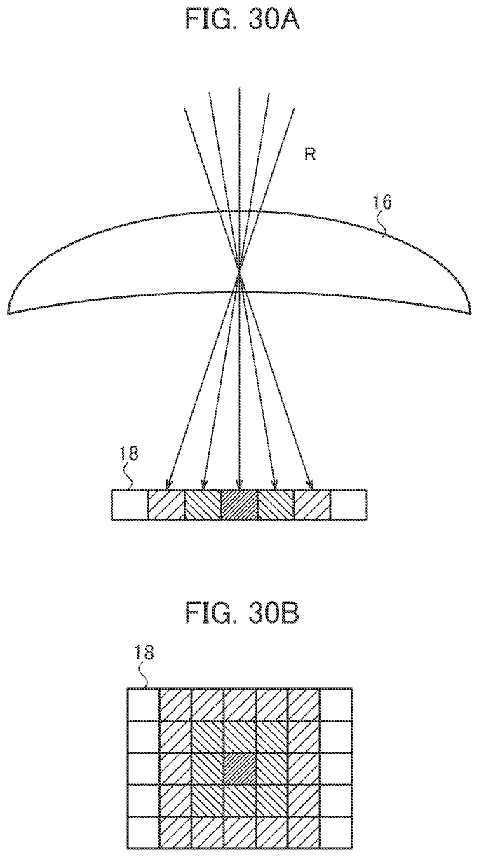

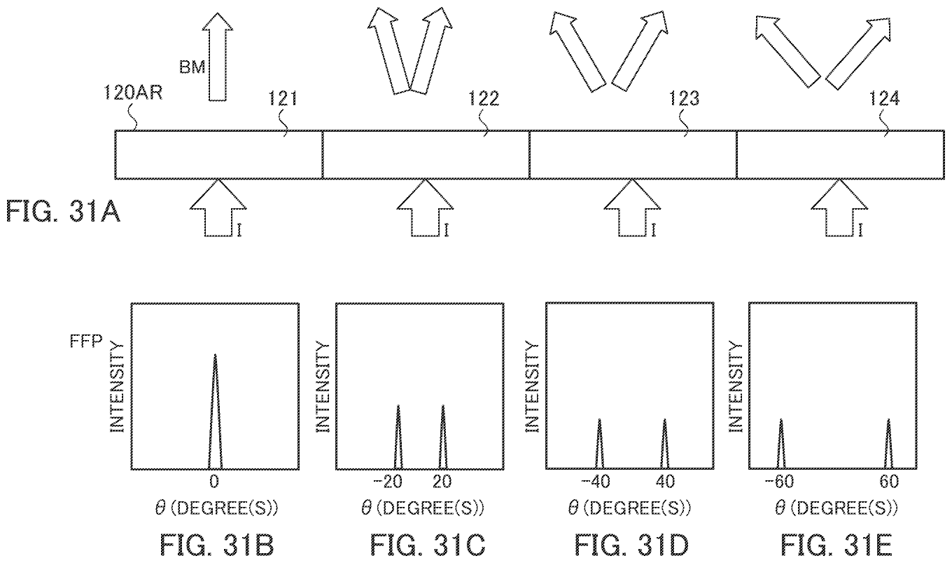

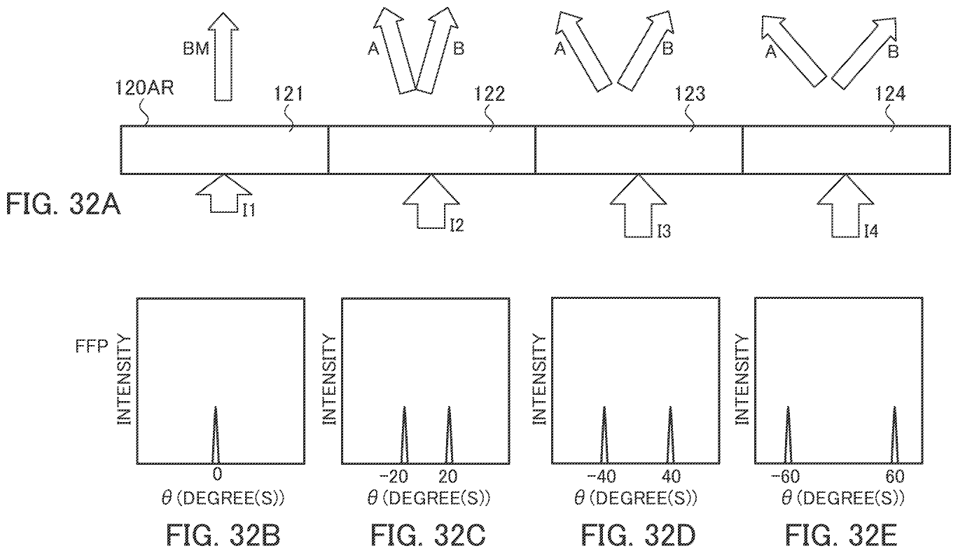

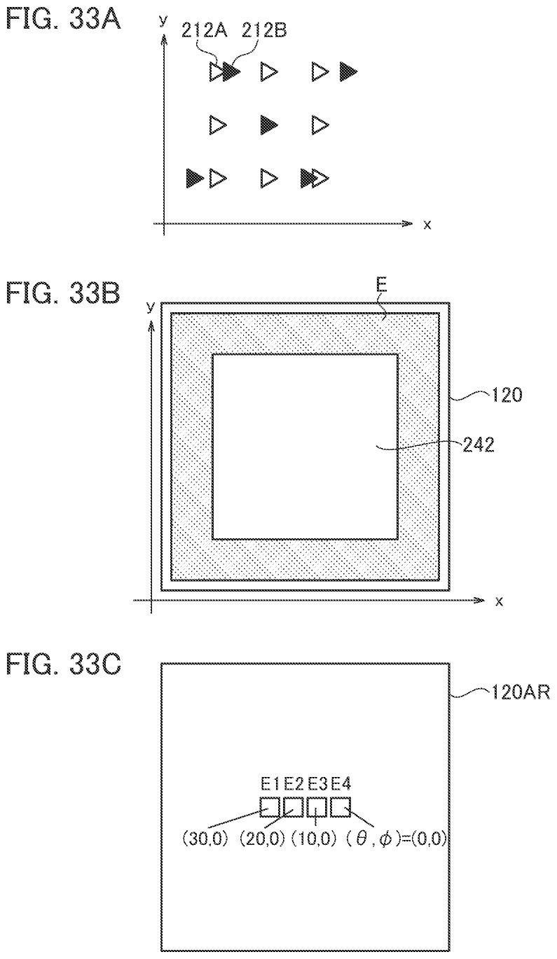

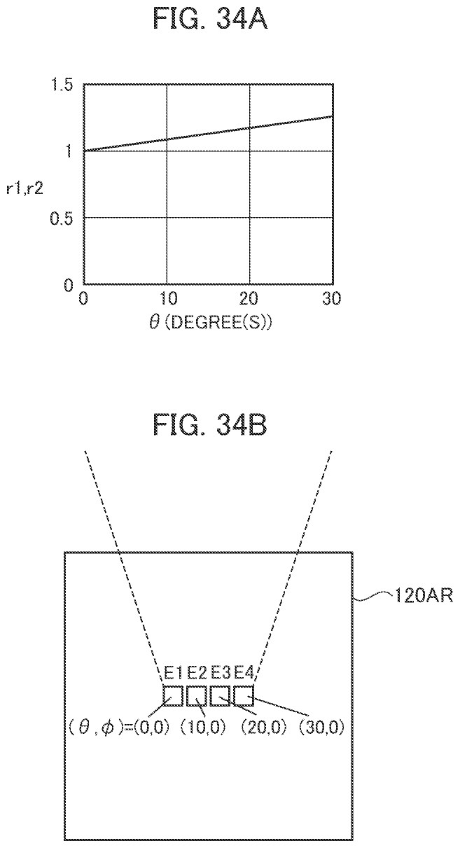

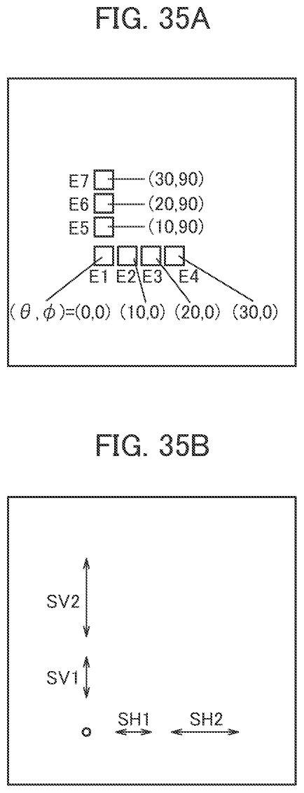

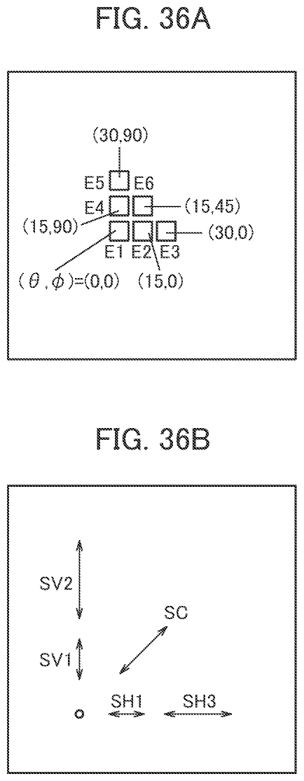

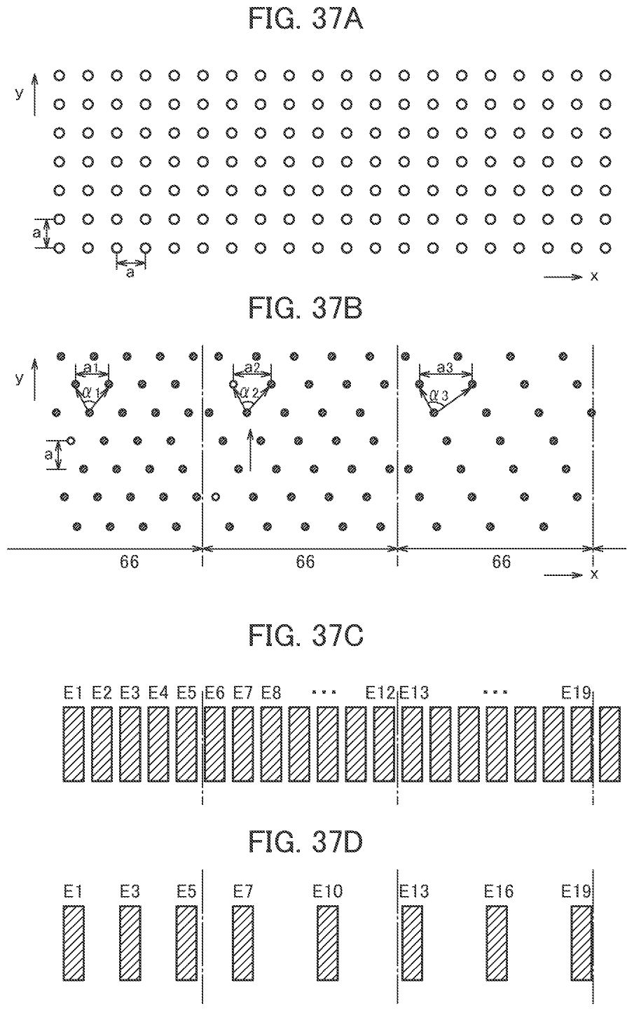

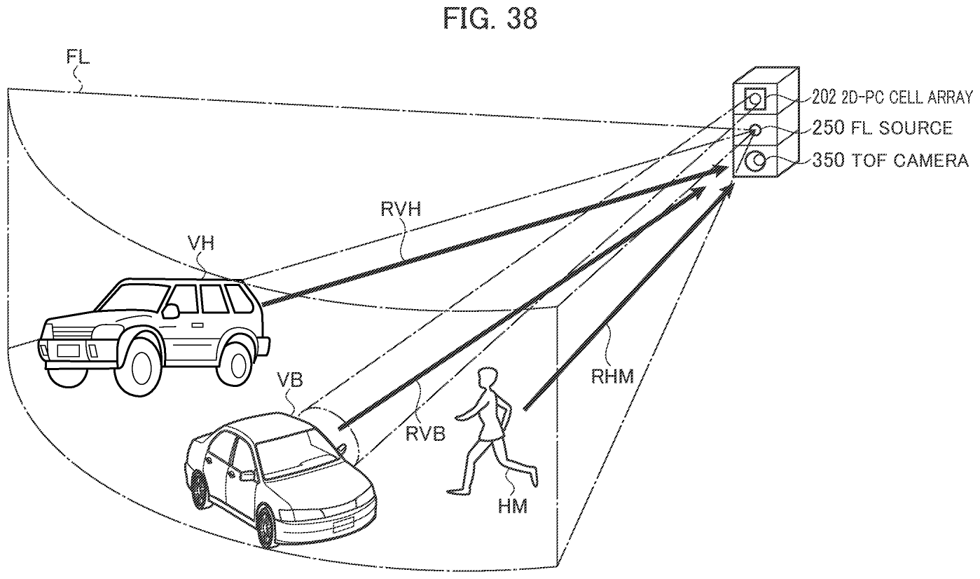

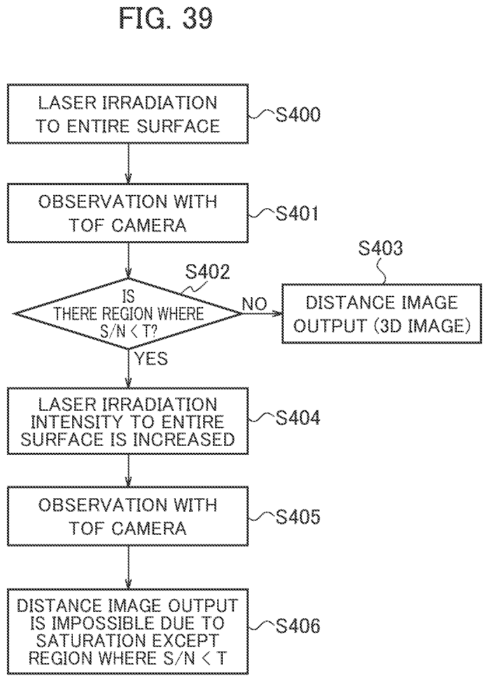

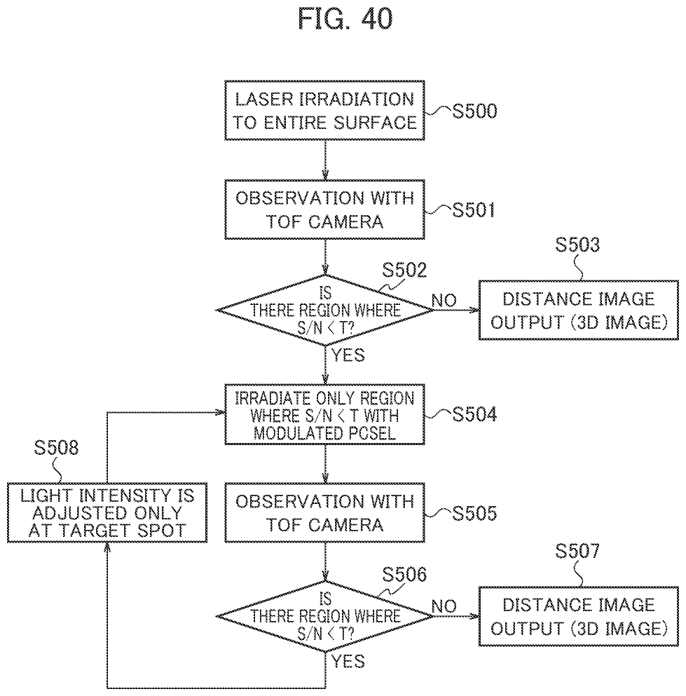

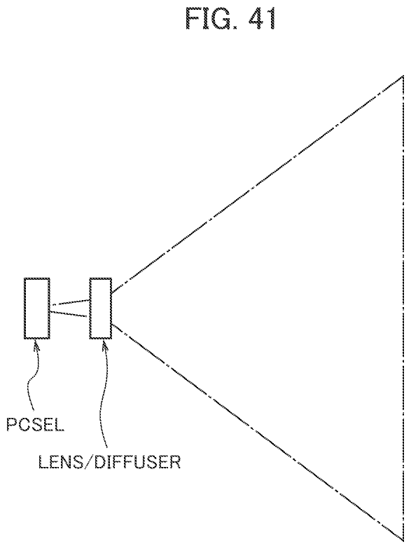

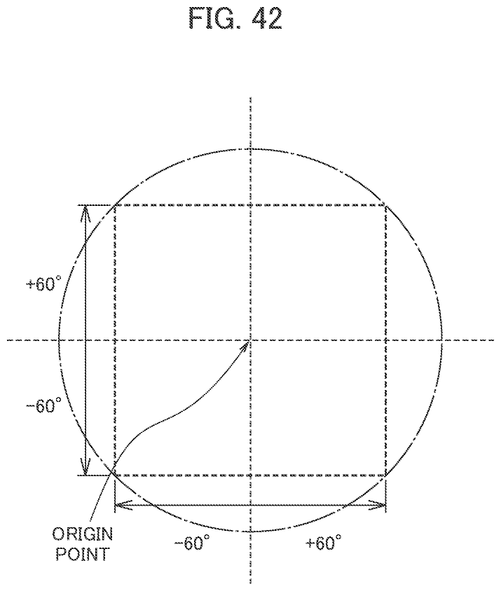

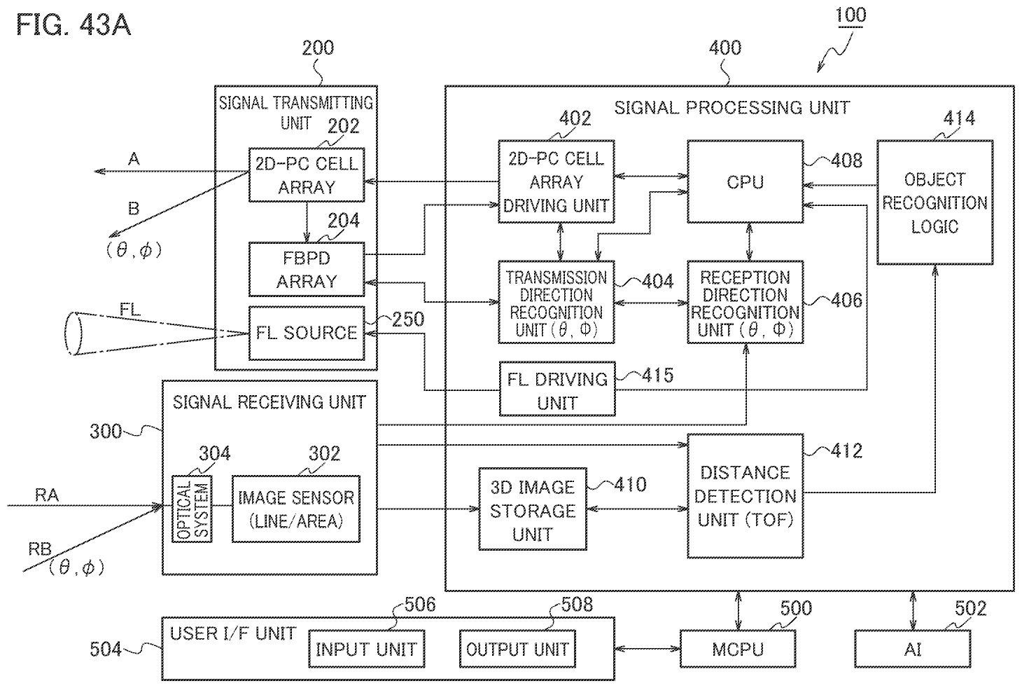

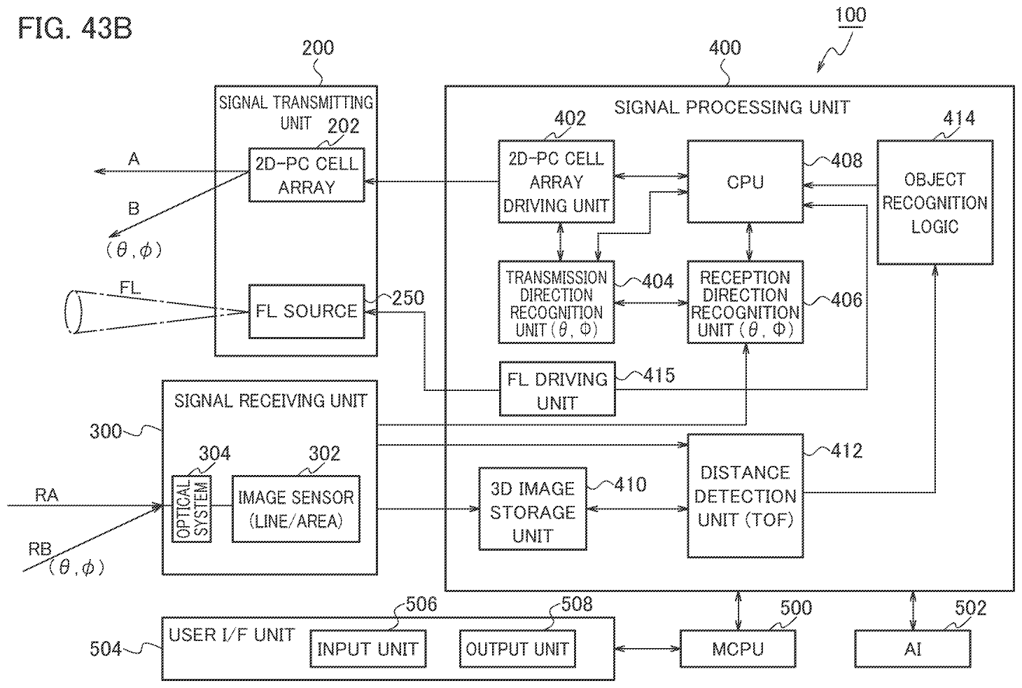

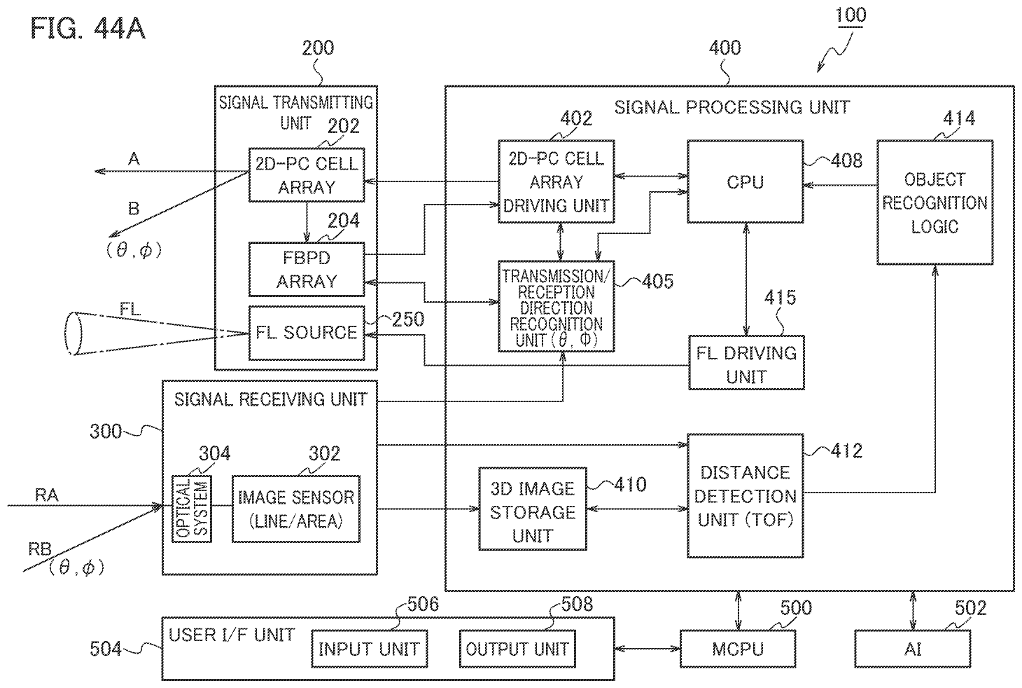

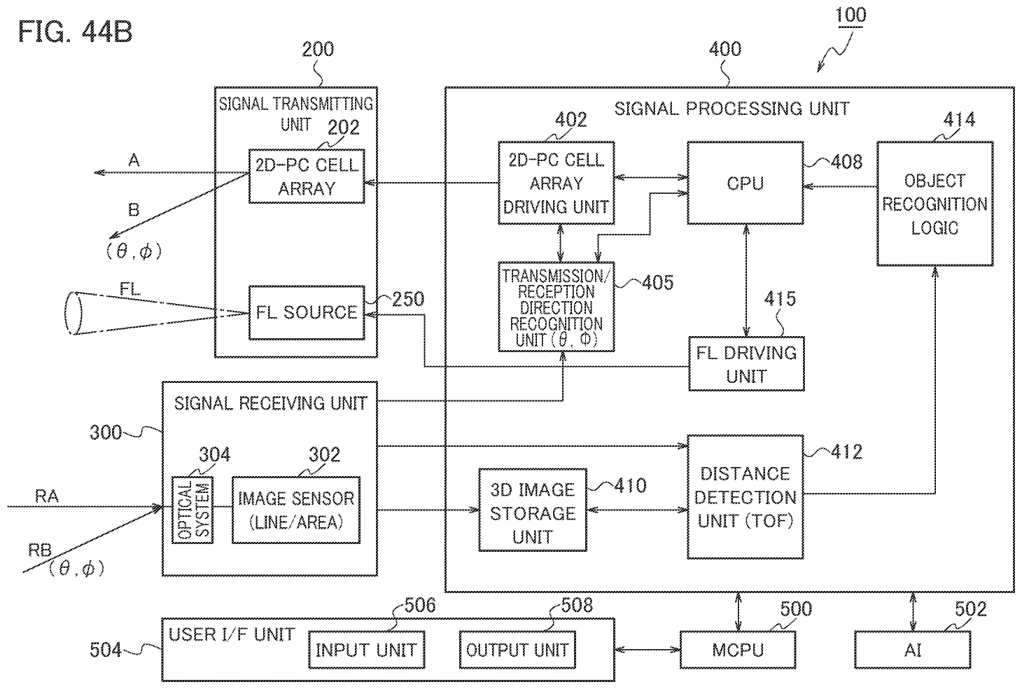

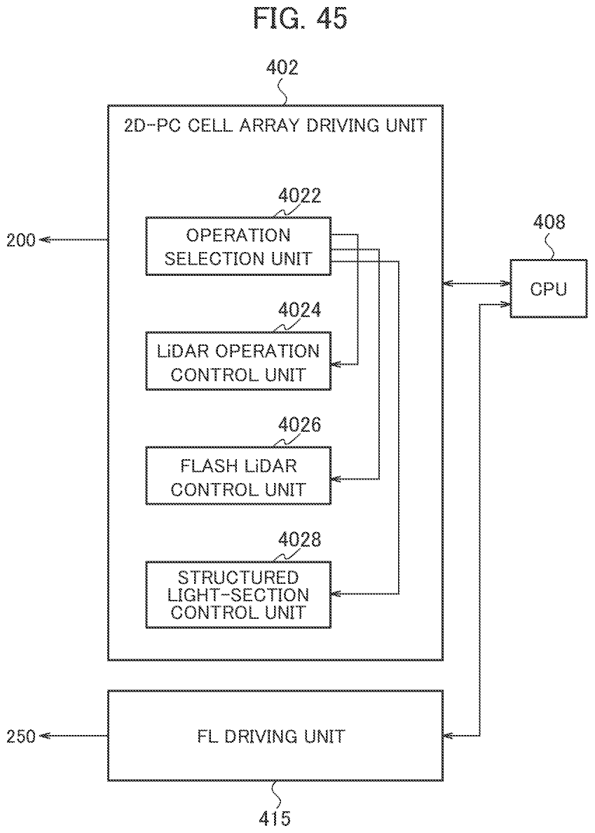

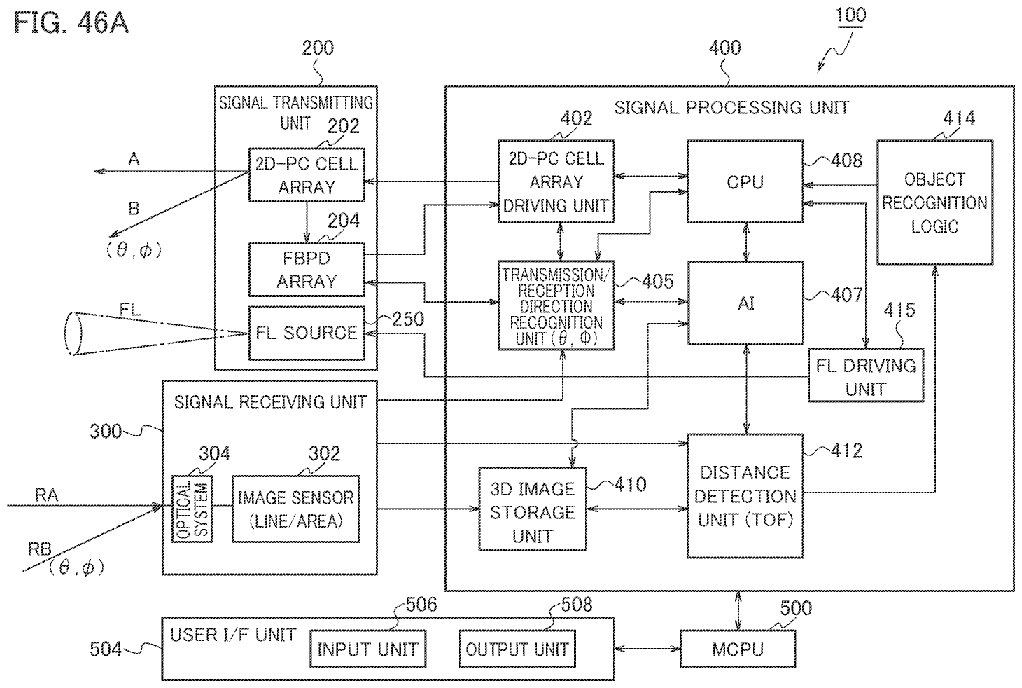

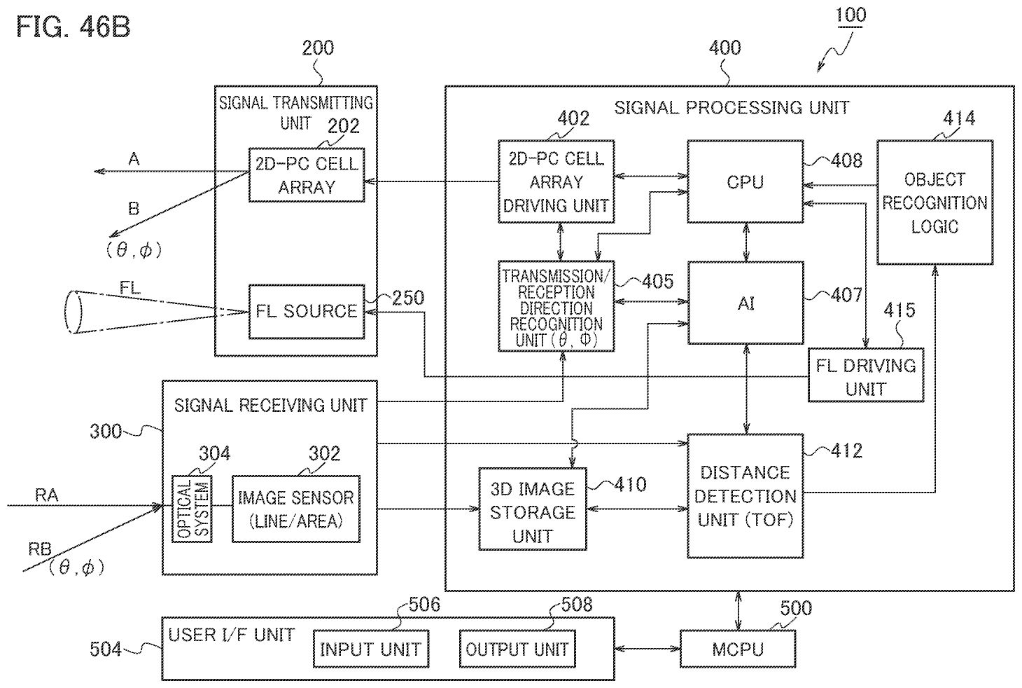

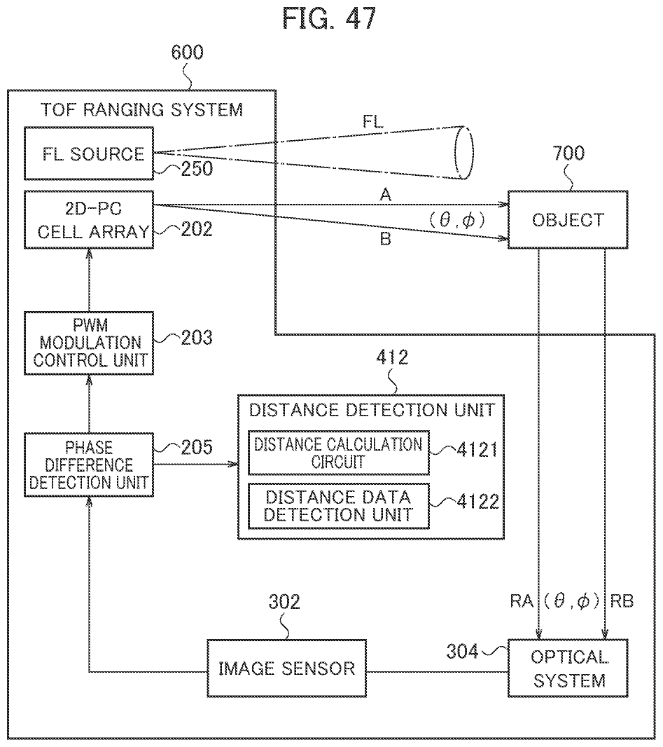

In the following description, the 2D-PC SEL described in Patent Literature 3 is used, but the modulated photonic crystal (PC) laser described in Patent Literature 2 may be used instead. The beam control principle is the same for both, and any one thereof can be used in the present embodiments. FIG. 1 illustrates a schematic bird's-eye view configuration of a 2D-PC SEL 120 applicable to a 3D sensing system according to the embodiments. FIG. 2 illustrates a schematic bird's-eye view configuration in which a transparent electrode 251T passing through a feedback laser light C (FB) is providing on a back side surface of the 2D-PC SEL 120.

FIGS. 1 and 2 schematically illustrate an aspect that laser light A, B is emitted from the surface thereof, and a feedback laser light C (FB) it is emitted from the back side surface thereof.

The PC laser applicable to the 3D sensing system according to the embodiments is formed by laminating a transparent electrode 251T, a lower substrate 241, a first cladding layer 231, a two-dimensional photonic crystal (2D-PC) layer 221, an active layer 222, a second cladding layer 232, an upper substrate 242, and a window-shaped electrode 252, in this order. In the PC laser in the embodiments, the laser beam (laser light A, B) is emitted passes through a cavity area (window) provided in a center portion of the window-shaped electrode 252 in a direction inclined by an emitting angle θ from a vertical line with respect to a surface at a side of the window-shaped electrode 252 of the upper substrate 242. It should be noted that the order of the 2D-PC layer 221 and the active layer 222 may be opposite to the above-mentioned order. For convenience, the words “upper” and “lower” are used in the embodiments, but these words do not define the actual orientation (upward or downward) of the PC laser.

In the embodiments, a p type semiconductor gallium arsenide (GaAs) is used for the lower substrate 241, an n type GaAs is used for the upper substrate 242, a p type semiconductor aluminum gallium arsenide (AlGaAs) is used for the first cladding layer 231, and an n type AlGaAs is used for the second cladding layer 232. A layer including a Multiple-Quantum Well (MQW) composed of an indium gallium arsenide/gallium arsenide (InGaAs/GaAs) is used for the active layer 222. Gold (Au) is used for the material of the window-shaped electrode 252. SnO₂, In₂O₃, or the like are used for the material of the transparent electrode 251T. Instead of the transparent electrode 251T, a Distributed Bragg Reflector (DBR) layer capable of passing through the laser light may also be used as a multilayered structure of an insulating layer. It should be noted that the materials of these each layer are not limited to the above-mentioned materials, and it is possible to use the same materials as those the materials used for the respective layers of conventional photonic crystal surface emitting laser (PC SEL). Moreover, other layers, such as a spacer layer, may be inserted between the above-mentioned each layer.

The 2D-PC layer 221 is formed by periodically arranging holes (different refractive index regions) 211 on the below-mentioned lattice points in a plate-shaped base material (slab) 214. A p type GaAs is used for the material of the slab 214 in the embodiments. Although the shape of the hole 211 is equilateral triangle in the embodiments, another shape, such as circular shape, may be used therefor. It should be noted that the material of the slab 214 is not limited to the above-mentioned material, and any material used for the base member in conventional PC lasers can also be used therefor. Moreover, any member (different refractive index member) from which the refractive index is different may be used for the different refractive index region in the slab 214 instead of the hole 211. The holes are advantageous in that they can be easily processed, while different refractive index members are preferable in the case where the base member may possibly be deformed due to a processing heat or other factors.

In the 2D-PC SEL 120 cell applicable to the 3D sensing system according to the embodiments, FIG. 3A is a top view diagram illustrating a state where a lattice 212A for forming optical resonance state is arranged as a lattice point where a hole (different refractive index region) is arranged at a 2D-PC layer 221; FIG. 3B is a top view diagram illustrating a state where a lattice 212B for light-emitting is arranged; FIG. 3C is a top view diagram illustrating a state where the lattice 212A for forming optical resonance state and the lattice 212B for light-emitting are arranged; and FIG. 3D is a top view diagram illustrating a state where a hole 211 is arranged.

The lattice point where the hole 211 is arranged, in the 2D-PC layer 221 will now be described with reference to FIG. 3. The 2D-PC layer 221 of the embodiments has a lattice 212A that forms a PC structure for forming optical resonance state (FIG. 3A) and a lattice 212B that forms a PC structure for light-emitting (FIG. 3B).

The lattice 212A for forming optical resonance state is composed of a square lattice having a lattice constant a. Hereinafter, in the square lattice, one of the two directions in which the lattice points 213A are aligned at interval a is referred to as the x direction and the other referred to as the y direction. Therefore, the x-y coordinate system of the lattice point 213A is expressed as (ma, na) using integers m and n.

In contrast, in the lattice 212B for light-emitting, an orthorhombic lattice having a basic translation vector of c₁↑=(r₁, 1)a and c₂↑=(r₂, 1)a is configured. The lattice constants c₁ and c₂ of this orthorhombic lattice are the magnitudes of the basic translation vector c₁↑ and c₂↑ are respectively (r₁^{0.5}+1)a and (r₂^{0.5}+1)a; and the angle α between c₁↑ and c₂↑ satisfies a relationship of cos α=(r₁r₂+1)×(r₁²+1)^{-0.5}×(r₂²+1)^{-0.5}. The lattice points 213B are aligned in the y direction at interval a, for both the lattice 212A for forming optical resonance state and the lattice 212B for light-emitting.

In the embodiments, the emission wavelength λ is 980 nm. Moreover, the effective refractive index n_{eff} of the 2D-PC layer 221 is determined by the refractive index (3.55) of the p type GaAs which is a material of the slab 214 and a rate of the hole 211 occupies in the slab 214 (refractive index 1). In the embodiments, the effective refractive index n_{eff} of the 2D-PC layer 221 is set to 3.5 by adjusting the area of the hole 211. Accordingly, the lattice constant a in the embodiments is set to 2^{-0.5}×980 nm/3.4≈200 nm from the equation (3) described below.

In the 2D-PC layer 221 of the embodiments, the PC structure is formed by arranging the hole 211 at the lattice point of the lattice 212C (FIG. 3C) by superposing the lattice 212A for forming optical resonance state and the lattice 212B for light-emitting (FIG. 3D).

In the 2D-PC layer 221 of the embodiments, the laser beam is emitted in the direction with which r₁ and r₂ which are parameters indicating the position of the lattice point 213B satisfy the equation (1) and the equation (2) described below.

In the 2D-PC SEL cell 120 applicable to the 3D sensing system according to the embodiments, FIG. 4A is a schematic diagram of emitted light (beam) A and emitted light (beam) B, and FIG. 4B is a schematic diagram for explaining an aspect that the emitted light A, B existing on the same plane are rotated.

By applying a periodic drive modulation to the PC structure and providing a diffraction effect to an upper side in addition to the resonance effect, the beam emitting direction control (beam scanning) covering the range of the biaxial direction can be executed.

As illustrated in FIG. 4A, two basic beams A and B to be emitted from the origin point O (also referred to as twin beam) are emitted simultaneously. Two beams A and B exist in the same plane PS. The direction of the beams A and B can be arbitrarily changed respectively within an inclined angle −θ and +θ from the 90° direction. However, the emitting directions of the beams A and B are symmetrical with respect to the inclined angle 0, and the two beams A and B are simultaneously emitted with the same power. It is also possible to relatively reduce the output of one beam (beam A or beam B) by introducing asymmetry with regard to the inclined angle θ, but the output cannot be completely to zero.

As illustrated in FIG. 4B, the plane PS can be arbitrarily rotated centering on the origin point O (e.g., in the direction of PS0→PS1→PS2). Accordingly, beam scanning in a cone centering on the origin point O can be realized by combining the scanning in the plane PS with the rotation of the plane PS. Moreover, an arbitrary trajectory can be drawn by executing simultaneous scanning with the two beams A and B in which the origin point O is symmetrical in the cone. Furthermore, a plurality of twin beams (A, B) in a plurality of element arrays can be independently controlled (e.g., the beams A and B in the plane PS1 and the plane PS2 illustrated in FIG. 4B are simultaneously emitted, and the inclined angle θ and the rotation thereof can be independently controlled respectively).

As a specific example of the twin beam A, B, the spreading angle of one beam (beam A or B) is 0.34°, the output of the twin beam A, B is 1 to 10 W, the modulation frequency is several hundreds of MHz, and |θ|<50°. Strictly speaking, not all beams are emitted from the origin point O, but since the transition is at most approximately μm, the beams may be regarded as emitted from the same point in the LiDAR applications for sensing from several meters to several hundred meters.

In the 2D-PC SEL cell 120 applicable to the 3D sensing system according to the embodiments, FIG. 5A illustrates a state where a lattice 212A for forming optical resonance state composed of square lattice is arranged as a lattice point where a hole (different refractive index region) is arranged at a 2D-PC layer 221; FIG. 5B is a top view diagram illustrating a state where a lattice 212B for light-emitting composed of orthorhombic lattice is arranged; and FIG. 5C illustrates a state where the lattice 212A for forming optical resonance state and the lattice 212B for light-emitting are arranged.

Used photonic crystal herein is a photonic crystal for beam scanning illustrated in FIG. 5C obtained by superposing the lattice for forming optical resonance state composed of square lattice illustrated in FIG. 5A and the lattice for light-emitting composed of orthorhombic lattice illustrated in FIG. 5B.

In the 2D-PC layer 221 of the embodiments, the laser beam is emitted in the direction with which r₁ and r₂ which are parameters indicating the position of the lattice point satisfy the equation (1) and the equation (2) as follows:

$$\begin{matrix}{r}_{1} = \frac{{n}_{eff} + \sqrt{2} sin θsinϕ}{{n}_{eff} - \sqrt{2} sin θ cos ϕ} & ( 1 ) \\ {r}_{2} = \frac{{n}_{eff} - \sqrt{2} sin θsinϕ}{{n}_{eff} - \sqrt{2} sin θ cos ϕ} & ( 2 )\end{matrix}$$

where θ is the inclined angle with respect to the normal line of the PC layer, φ is the azimuth angle with respect to the x direction, and n_{eff} is the effective refractive index.

Moreover, the lattice constant a in the 2D-PC layer 221 of the embodiments is obtained by the following equation (3):

$$a = \frac{1}{\sqrt{2}} \frac{λ}{{n}_{eff}} \qquad ( 3 )$$

where λ is the emission wavelength.

The 2D-PC layer 221 of the embodiments designed in this way enables the beams A and B to be emitted in the biaxial directions.

### [Feedback Control of 2D-PC SEL]

FIG. 6A schematically illustrates an example of output characteristics indicating a relationship between the laser light intensity L of the emitted light A, B and the injection current I, in the 2D-PC SEL cell 120 applicable to the 3D sensing system according to the embodiments. FIG. 6B schematically illustrates a structural example of the 2D-PC SEL cell 120 including a transparent electrode (or DBR layer) 251T passing through the feedback laser light C (FB) and a photo diode (PD) 118PD configured to detect laser light C (FB), on the back side surface thereof.

FIG. 7 illustrates a schematic block configuration diagram of a feedback control mechanism formed by combining a 2D-PC SEL cell array 120AR and the 2D-PD cell array 118PDAR, in the 3D sensing system according to the embodiments.

The feedback control mechanism includes: the 2D-PC SEL cell array 120AR; the 2D-PD cell array 118PDAR configured to detects the feedback laser light C (FB) from each cell emitted from a back side surface of the 2D-PC SEL cell array 120AR; a feedback control unit 130 configured to control a 2D-PD array driving unit 140AR on the basis of the detection result by the 2D-PD cell array 118PDAR; and the 2D-PD array driving unit 140AR configured to drive the 2D-PC SEL cell array 120AR in accordance with the control by the feedback control unit 130.

For example, even if the same current I is injected into each cell of the 2D-PC SEL cell array 120AR, the light intensity L may be different from each other depending on the direction (position) thereof. However, the light intensity L can be uniformed by configuring the feedback control mechanism as illustrated in FIG. 7, detecting a variation in the light intensity L in the 2D-PC SEL cell array 120AR on the basis of the feedback laser light C (FB), and executing drive control so that the injection current I may be changed for each cell of the 2D-PC SEL cell array 120AR.

FIG. 8 schematically illustrates an alternative structural example of the feedback control mechanism provided in the 3D sensing system according to the embodiments. The feedback control mechanism illustrated in FIG. 8 as an example is formed by laminating the 2D-PC SEL cell array 120AR and the two-dimensional photo diode (2D-PD) cell array 118PDAR so as to insert a transparent electrode (or DBR layer+transparent electrode) 251T therebetween to be combined.

FIG. 9 schematically illustrates an example of a plane configuration of the 2D-PC SEL cell array 120AR, and FIG. 10 schematically illustrates an example of a plane configuration of 2D-PD cell array 118PDAR, each applicable to the 3D sensing system according to the embodiments.

As illustrated in FIG. 9, the 2D-PC SEL cell array 120AR is composed of 2D-PC SEL cells having n columns×m rows. For example, n pieces of 2D-PC SEL cells (C₁₁ to C₁ₙ) are arranged in the first row, n pieces of 2D-PC SEL cells (C₂₁ to C₂ₙ) are arranged in the second row, . . . , and n pieces of 2D-PC SEL cells (Cₘ₁ to Cₘₙ) are arranged in the m-th row.

As illustrated in FIG. 10, the 2D-PD cell array 118PDAR is composed of 2D-PD cells having n columns×m rows. For example, n pieces of 2D-PD cells (PD₁₁ to PD₁ₙ) are arranged in the first row, n pieces of 2D-PD cells (PD₂₁ to PD₂ₙ) are arranged in the second row, . . . , and n pieces of 2D-PD cells (PDₘ₁ to PDₘₙ) are arranged in the m-th row.

### [3D Sensing System According to Embodiments]

### (Schematic Structure of 3D Sensing System)

FIG. 11 schematically illustrates an example of a schematic structure of the 3D sensing system according to the embodiments.

As illustrated in FIG. 11, the 3D sensing system according to the embodiments includes: a PC laser array 10 in which PC laser elements are arranged on a plane; a control unit 14 configured to control an operation mode of a laser light source; a driving unit 12 configured to execute a drive control of the PC laser array 10 in accordance with an operation mode controlled by the control unit 14; a light receiving unit (an imaging lens 16 and a TOF image sensor (or an arrayed light-receiving element having a function of TOF measurement, hereinafter simply referred to as an image sensor or an arrayed light-receiving element) 18) configured to receive a scattered reflected light emitted from the PC laser array 10 and reflected from a measuring object; a signal processing unit 20 configured to execute signal processing of the reflected light received by the light receiving unit in accordance with the operation mode controlled by the control unit 14; and a distance calculation unit 22 configured to execute calculation processing of a distance to the measuring object with respect to a signal processed by the signal processing unit 20, in accordance with the operation mode controlled by the control unit 14, and to output a calculation result as distance data DM.

The PC laser array 10 is a device in which the PC laser elements as illustrated in FIGS. 1 to 5 are arranged on a plane.

The control unit 14 executes the operation control of each unit on the basis of three operation modes (i.e., a LiDAR operation mode, a flash LiDAR operation mode, and a light-section method operation mode).

The driving unit 12 executes the drive control of beam emitted from the PC laser array 10 in accordance with the operation modes (LiDAR operation mode/flash LiDAR operation mode/light-section method operation mode) controlled by the control unit 14.

In addition, a feedback control illustrated in FIGS. 6 to 10 is included in the drive control executed by the driving unit 12. More specifically, the transparent electrode or DBR layer (251T) passing through the feedback laser light C (FB), and the photo diode (PD) (118PD) configured to detect the feedback laser light C (FB) are further included therein; the driving unit 12 detects a variation in the light intensity L in the PC laser array 10 on the basis of the feedback laser light C (FB), and the drive control is executed so that the injection current I is changed for each cell of the photonic crystal (PC) laser array 10, and thereby the light intensity L can be uniformed.

The light receiving unit including the imaging lens 16 and the image sensor (or arrayed light-receiving element) 18 receives the scattered reflected light emitted from the PC laser array 10 and reflected from the object through the imaging lens 16 by the image sensor (or arrayed light-receiving element) 18.

The signal processing unit 20 executes signal processing of the reflected laser beam received by the light receiving unit in accordance with the operation mode (LiDAR operation mode/flash LiDAR operation mode/light-section method operation mode) controlled by the control unit 14, to be transmitted to the distance calculation unit 22. The measurement principle of the LiDAR operation mode and the measurement principle of the flash LiDAR operation mode are equal in that the reflection from the plurality of beams emitted from the PC laser array 10 is captured by the image sensor and the distance thereto is calculated by the time measurement function. The difference between both is resolution (positional accuracy) of the space to be measured. The resolution in LiDAR mode depends on the emitting direction accuracy of the emitting beam, and the resolution in the flash LiDAR operation mode depends on the number of pixels with respect to a certain angle of view.

The distance calculation unit 22 calculates the distance to the measuring object on the basis of the light receiving position in the imaging surface of the image sensor 18 and the time from light emission to light reception (arrival time) in accordance with the operation mode (LiDAR operation mode/flash LiDAR operation mode/light-section method operation mode) controlled by the control unit 14, and outputs the calculation result as the distance data DM.

### (Distance Calculation Processing)

FIG. 12 illustrates an example of distance calculation procedure of three operation modes in the 3D sensing system according to the embodiments.

The distance calculation processing is started in Step S0.

In Step S1, in accordance with the operation mode controlled by the control unit 14, the driving unit 12 executes the drive control of the PC laser array 10, and the laser beam is emitted from the PC laser array 10. More specifically, any one of emitting the twin beam/emitting in regional shape/emitting optical pattern are selected, in accordance with three operation modes (LiDAR operation mode (M1)/flash LiDAR operation mode (M2)/light-section method operation mode (M3)), and the beam is emitted from the PC laser array 10. Namely, when the operation mode is the LiDAR operation mode, one laser element is driven and the twin beam (A, B) is emitted in a certain direction; when the operation mode is the flash LiDAR operation mode, a certain region (sensing space) is irradiated with the light for given length of time; and when the operation mode is the light-section method operation mode, striped pattern light is projected onto the measuring object.

In Step S2, the light receiving unit (16, 18) receives the scattered reflected light emitted from the PC laser array 10 and then reflected from the measuring object by the image sensor (or arrayed light-receiving element) 18 through the imaging lens 16.

In Step S3, the control unit 14 allocates the processing, in accordance with the operation mode, to any one of Step S4, Step S5 and Step S6. More specifically, when the operation mode is a LiDAR operation mode (M1) (emitting twin beam), the processing shifts to Step S4; when the operation mode is the flash LiDAR operation mode (M2) (emitting in regional shape), the processing shifts to Step S5; and when the operation mode is the light-section method operation mode (M3) (emitting optical pattern), it changes to Step S6.

When the operation mode is the LiDAR operation mode (M1) (emitting twin beam), in Step S4, the distance calculation unit 22 separates the reflected light emitted and reflected from the measuring object from each beam, and calculates the distance to the measuring object on the basis of the reflected light arrival time (TOF). As a result, information of the distance to and the direction of the measuring object which exist in the direction where the beam is emitted is obtained, and the distance calculation unit 22 outputs the obtained information as the distance data DM1 (FIG. 13), in Step S5. Here, in the separation processing of reflected light, the reflected light is separated by detecting which pixel (pixels) of the image sensor 18 received the light. Since the emitting direction of twin beam from the PC laser array 10 is obvious, the arrival direction of the reflected light due thereto can also be identified. If there is a certain reflected light, it can be determined whether or not the pixel in the image sensor 18 corresponding to the arrival direction of the reflected light receives the light, and thereby the arrival time can also be measured. If the image sensor capable of the separation, a plurality of twin beams can also be simultaneously emitted.

When the operation mode is the flash LiDAR (M2) (emitting in regional shape), in Step S5, the distance calculation unit 22 calculates the distance for each pixel on the basis of the pixel position and the reflected light arrival time for each pixel. As the result, the distance information for each pixel of the distance to the measuring object which exists in the emission region can be obtained, and the distance calculation unit 22 outputs the obtained information as the distance data DM2 (FIG. 13), in Step S5.

When the operation mode is the light-section method (M3) (emitting optical pattern), in Step S6, the distance calculation unit 22 executes triangular ranging with the stripe-shaped imaging pattern projected onto the measuring object, and thereby calculates the distance to the measuring object. As a result, the three-dimensional (3D) data of the measuring object can be obtained by moving the distance information and the line along the projected striped pattern light, and the distance calculation unit 22 outputs the obtained information as the distance data DM3 (FIG. 13), in Step S5.

### (Operation Mode in 3D Sensing System)

FIG. 13 illustrates an example of an operational flowchart of three operation modes in 3D sensing system according to the embodiments.

In Step S11, the control unit 14 executes operation control of the driving unit 12 and the distance calculation unit 22 on the basis of three operation modes (i.e., the LiDAR operation mode, the flash LiDAR operation mode, the light-section method operation mode).

In Step S12, the driving unit 12 executes the drive control of the PC laser array 10 in accordance with the following three operation modes.
(1) LiDAR operation mode (M1): one laser element is driven to emit twin beam (A, B) in a certain direction.
(2) Flash LiDAR operation mode (M2): A region is irradiated with light for given length of time (multiple elements emitting two beams are simultaneously driven, or a single or multiple elements with controlled spreading angle are made to emit simultaneously).
(3) Light-section method operation mode (M3): a plurality of elements are simultaneously driven to project the striped pattern light onto the measuring object.

Then, when the light receiving unit (16, 18) receives the scattered reflected light emitted from the PC laser array 10 and reflected from the measuring object, the signal processing unit 20 and the distance calculation unit 22 execute processing in accordance with the operation mode.

More specifically, when the operation mode is M1 or M2 in Step S13, the distance calculation unit 22 measures the arrival time of the reflected light for each pixel in Step S14, and when the operation mode is M1 in Step S16, the distance calculation unit 22, in Step S17, executes correspondence processing to the emitting beam, calculates the distance to the measuring object on the basis of the arrival time of the emitted beam, and outputs the calculates distance as the distance data DM1. In contrast, when the operation mode is M2 in Step S16, the distance calculation unit 22 outputs the information obtained on the basis of the arrival time of the reflected light measured in Step S14 as the distance data DM2.

On the other hand, when the operation mode is M3 in Step S13, the distance calculation unit 22 obtains a reflected light image (imaging pattern) (pixel) in Step S15, and the distance calculation unit 22, in Step S18, executes triangular ranging with the imaging pattern, calculates the distance to the measuring object, and outputs the calculated distance as the distance data DM3.

### (Operational Principle of LiDAR Operation Mode (M1))

FIG. 14A schematically illustrates an operational principle for detecting reflected light RA and reflected light RB with respect to the emitted light A and emitted light B by the image sensor 18, and FIG. 14B illustrates a conceptual diagram of the image sensor 18 for detecting the reflected light RA and reflected light RB, in the LiDAR operation mode executed in the 3D sensing system according to the embodiments.

From one element of the PC laser array 10, two beams (twin beam) A and B are emitted in accordance with an angle specification based on the design thereof. In an example of FIG. 14A, the emitted light A is reflected from the measuring object 24T1 and is received by the image sensor 18 through the imaging lens 16 as the reflected light RA, and the emitted light B is reflected from the measuring object 24T2 and is received by the image sensor 18 through the imaging lens 16 as the reflected light RB. In this case, if there is no reflected light, it can be recognized as that no object (no measuring object) exists in the corresponding direction.

When the reflected light RA and the reflected light RB is detected, the distance calculation unit 22 determines which beam of the emitted light A or B is the reflected light on the basis of a light receiving position (x, y) on the imaging surface of the image sensor 18, and measures the time from light emission to light reception. For example, it can be identified that the light receiving position 24I1 in the image sensor 18 illustrated in FIG. 14B corresponds to a light receiving position of the reflected light RA from the measuring object 24T1 and the light receiving position 24I2 corresponds to a light receiving position of the reflected light RB from the measuring object 24T2. Accordingly, it is possible to identify which direction of the emitted light A or B is the reflected light RA or RB on the basis of the light receiving position (x, y) in the imaging surface of the image sensor 18. If the image sensor 18 has a sufficient resolution to cover the angular resolution of the twin beam A, B, it is possible to separate the imaging position (x, y) for each beam.

The distance calculation unit 22 calculates the distance to each of the measuring objects 24T1 and 24T2 existing in the emitting direction of the twin beam A, B, on the basis of the above information. Herein, the distance to each of the measuring object 24T1 and 24T2=the light velocity×the arrival time/2.

In the LiDAR operation mode in the 3D sensing system according to the embodiments, the above distance calculation is repeatedly executed with respect to different emitting directions.

### (Operational Principle of Flash LiDAR Operation Mode (M2))

FIG. 15A schematically illustrates an operational principle for detecting a reflected light RFL with respect to emitted light FL by the image sensor, and FIG. 15B illustrates a conceptual diagram of the image sensor configured to detect the reflected light RFL, in a flash LiDAR operation mode executed in the 3D sensing system according to the embodiments.

From a plurality of elements in the PC laser array 10, laser light FL is simultaneously emitted to a specific region. In an example illustrated in FIG. 15A, the emitted light FL is reflected from the measuring objects 24T1 and 24T2 and is received by the image sensor 18 through the imaging lens 16 as the reflected light RFL. In this case, if there is no reflected light, it can be recognized as that no object (no measuring object) exists in the corresponding direction.

The distance calculation unit 22 measures the arrival time (time from light emission to light reception) of the reflected light for each pixel, when the reflected light RFL is detected. For example, it can be identified that the light receiving position 24I1 in the illumination area ILL of the image sensor 18 illustrated in FIG. 15B corresponds to a light receiving position of the reflected light RFL from the measuring object 24T1 and the light receiving position 24I2 corresponds to a light receiving position of the reflected light RFL from the measuring object 24T2.

The distance calculation unit 22 calculates the distance to each of the measuring objects 24T1 and 24T2 existing in the imaging range for each pixel on the basis of the above information. In the flash LiDAR operation mode, the distance information according to the number of the pixels in the illumination area ILL can be acquired at once.

### Operational Principle of Light-Section Method (Structured Light Projection) Operation Mode (M3)

FIG. 16A schematically illustrates an operational principle for detecting reflected light RST with respect to rotating stripe-shaped emitted light ST by the image sensor, and FIG. 16B illustrates a conceptual diagram of the image sensor configured to detect the reflected light RST, in the light-section method operation mode (also referred to as the structured light projection operation mode) in the 3D sensing system according to the embodiments. Moreover, FIG. 17 illustrates a detail example of an operation of detecting the reflected light RST corresponding to the rotating stripe-shaped emitted light ST by the image sensor, in the light-section method operation mode executed in the 3D sensing system according to the embodiments.

An example of 3D measurement operation by means of the structured light projection will now be described as a light-section method operation, with reference to FIGS. 16 to 17. Not only this method, but also some measurements using pattern illumination can be supported. The light-section method can also be applied to a method of comparing the light receiving pattern of the stripe-shaped light or random dotted pattern light with respect to a reference shape with the actual light receiving pattern and calculating the shape from the deviation thereof, etc. (e.g., face recognition function to be used for mobile phones).

In the light-section method operation mode, the measuring object 24T is irradiated with stripe-shaped laser light ST generated by the PC laser array 10. In an example illustrated in FIG. 16A, the emitted light ST is reflected from the measuring object 24T and is received by the image sensor 18 through the imaging lens 16 as the reflected light RST (24I). In this case, if there is no reflected light, it can be recognized as that no object (no measuring object) exists in the corresponding direction.

The distance calculation unit 22, when the reflected light RST is detected, obtains a reflected light image (imaging pattern) (pixel), executes triangular ranging with the imaging pattern, calculates the distance to the measuring object 24T, and obtains 3D distance data for one line of the stripe-shaped light.

Furthermore, as illustrated in FIG. 16A, 3D data of the entire measuring object 24T can be obtained by rotationally scanning the stripe-shaped light ST (ROT).

A positional relationship between the PC laser array 10, the measuring object 24T, the imaging lens 16, and the image sensor 18, which are illustrated to FIG. 17, is obtained by the following equation:

X=D cos θₐ sin θ_{b}/sin(θₐ+θ_{b}) (4)

Y=D sin θₐ sin θ_{b}/sin(θₐ+θ_{b}) (5)

Z=D tan φₐ/sin θₐ (6)

where θₐ=tan⁻¹(f/Xₐ), φₐ=tan⁻¹(Yₐ cos θₐ/Xₐ),

D is baseline length, f is the focal length of the imaging lens 16, and Xₐ and Yₐ are positions of spot light image on the image sensor 18.

### (Operation Flow of LiDAR Operation Mode (M1))

FIG. 18 illustrates a flow chart of the LiDAR operation mode in the 3D sensing system according to the embodiments.

First, in Step S101, twin beam A, B is emitted in a specific direction from one element (specific element) in the PC laser array 10.

Next, in Step S102, the reflected light RA and reflected light RB emitted from the PC laser array 10 and respectively reflected from the measuring objects 24T1 and 24T2 are captured by image sensor 18 through the imaging lens 16. In this case, if there is no reflected light, it can be recognized as that no object (no measuring object) exists in the corresponding direction.

Next, in Step S103, the distance calculation unit 22 distinguishes which beam of the emitted light A or B is the reflected light from the light receiving position (position of pixel) on the imaging surface of the image sensor 18.

Next, in Step S104, the distance calculation unit 22 measures the arrival time of the reflected light from each of the measuring objects 24T1 and 24T2 to the pixel of the image sensor 18.

Next, in Step S105, the distance calculation unit 22 calculates the distance to each of the measuring objects 24T1 and 24T2 existing in the emitting direction of the laser light A and B on the basis of the information of each of the emitting light A and emitting light B distinguished in the position of the pixel in the image sensor 18 and the information of the arrival time of each of the reflected light RA and reflected light RB from the measuring object to the pixel in image sensor 18.

The above-described distance calculation is repeated for different emitting directions (Step S106).

### (Operation Flow of Flash LiDAR Operation Mode (M2))

FIG. 19 illustrates a flow chart of the flash LiDAR operation mode, in the 3D sensing system according to the embodiments.

First, in Step S201, from a plurality of elements in the PC laser array 10, laser light FL is simultaneously emitted to a specific region.

Next, in Step S202, the reflected light RFL emitted from the PC laser array 10 and reflected from the measuring objects 24T1 and 24T2 is captured by image sensor 18 through the imaging lens 16. In this case, if there is no reflected light, it can be recognized as that no object (no measuring object) exists in the corresponding direction.

Next, in Step S203, when the reflected light RFL is detected, the distance calculation unit 22 measures the arrival time (time from light emission to light reception) of the reflected light in each pixel.

Next, in Step S204, the distance calculation unit 22 calculates the distance to each of the measuring objects 24T1 and 24T2 existing in the imaging range for each pixel. In the flash LiDAR operation mode, the distance information according to the number of the pixels in the illumination area ILL can be acquired at once.

### (Operation Flow of Light-Section Method (Structured Light Projection) Operation Mode (M3))

FIG. 20 illustrates a flow chart of the light-section method operation mode, in the 3D sensing system according to the embodiments.

First, in Step S301, the measuring object 24T is irradiated with stripe-shaped light ST generated by the PC laser array 10.

Next, in Step S302, the reflected light RST emitted from the PC laser array 10 and reflected from the measuring object 24T is received by image sensor 18 through the imaging lens 16. The distance calculation unit 22 obtains a reflected light image (imaging pattern) (pixel), executes triangular ranging with the imaging pattern, calculates the distance to the measuring object 24T, and obtains 3D distance data for one line of the stripe-shaped light.

Next, in Step S303, 3D data of the entire measuring object 24T is obtained by rotationally scanning stripe-shaped light ST (ROT).

### (Block Configuration of 3D Sensing System)

FIG. 21 schematically illustrates an example of a block structure of the 3D sensing system 100 according to the embodiments. Moreover, FIG. 21B schematically illustrates an alternative block structural example of the 3D sensing system according to the embodiments. The difference between the structure in FIG. 21A and the structure in FIG. 21B is that the signal transmitting unit 200 includes a feedback photo diode (FBPD) array 204 in FIG. 21A, while the signal transmitting unit 200 includes no FBPD array 204 in FIG. 21B. In this way, the FBPD array 204 may be included or may be omitted. Since the feedback operation can be executed also by a camera, the FBPD array 204 may be omitted.

As illustrated in FIG. 21A, the 3D sensing system 100 according to the embodiments includes: a signal transmitting unit 200 including a two-dimensional photonic crystal (2D-PC) cell array 202 configured to emit laser light to a measuring object; a signal receiving unit 300 including an optical system 304 and an image sensor 302, configured to receive reflected light emitted from the signal transmitting unit 200 and reflected from the measuring object; and a signal transmitting unit 200. The signal transmitting unit 200 includes: a control unit (CPU) 408 configured to control an operation mode of the laser light source; a transmission direction recognition unit 404 configured to recognize an emitting direction of the laser light emitted from the 2D-PC cell array 202; a 2D-PC cell array driving unit 402 configured to executes a drive control of the 2D-PC cell array 202 in accordance with the operation mode controlled by the CPU 408 on the basis of the emitting direction of laser light recognized by the transmission direction recognition unit 404; and a distance detection unit (TOF) 412 configured to calculate the distance to the measuring object on the basis of a light receiving position on an imaging surface of the image sensor 18 and the time from light emission to light reception, in accordance with the operation mode controlled by the CPU 408.

The signal transmitting unit 200 further includes the FBPD array 204 configured to execute a feedback control of the emitted laser light, and the transmission direction recognition unit 404 recognizes an emitting direction of the laser light emitted from the signal transmitting unit 200 in accordance with feedback information provided from the FBPD array 204.

The signal transmitting unit 200 may also include a reception direction recognition unit 406 configured to recognize a reception direction of the reflected light from the light receiving position on the imaging surface of the image sensor 18, and the 2D-PC cell array driving unit 402 executes a drive control of the 2D-PC cell array 202 on the basis of the emitting direction of the laser light recognized by the transmission direction recognition unit 404 and the reception direction of the reflected light recognized by the reception direction recognition unit 406.

The signal transmitting unit 200 further includes an object recognition logic 414 configured to identify the measuring object on the basis of a calculation result of the distance detection unit (TOF) 412.

More specifically, as illustrated in FIG. 21A, the 3D sensing system 100 according to the embodiments includes a signal transmitting unit 200, a signal receiving unit 300, a signal processing unit 400, a main controlling unit (MCPU) 500, and an artificial intelligence (AI) unit 502.

The signal transmitting unit 200 includes a 2D-PC cell array 202 configured to emit laser light to a measuring object, and an FBPD array 204 configured to execute a feedback control of the emitted laser light. The 2D-PC cell array 202 corresponds to the PC laser array 10 illustrated to FIG. 11, for example, and the FBPD array 204 corresponds to the photo diode (PD) 118PD illustrated in FIG. 6 or the 2D-PC 118PDAR illustrated in FIG. 8.

The signal receiving unit 300 includes an optical system 304 and an image sensor (line/area) 302 configured to receive a scattered reflected light emitted from the signal transmitting unit 200 and reflected from the measuring object. The optical system 304 and the image sensor 302 respectively correspond to the imaging lens 16 and the image sensor 18 which are illustrated in FIG. 11.

The signal processing unit 400 includes a 2D-PC cell array driving unit 402, a transmission direction recognition unit 404, a reception direction recognition unit 406, a CPU 408, a 3D image storage unit 410, a distance detection unit (TOF) 412, and an object recognition logic 414. The CPU 408 executes an operation control of each unit on the basis of three operation modes (i.e., LiDAR operation mode, flash LiDAR operation mode, light-section method operation mode). The CPU 408 corresponds to the control unit 14 illustrated in FIG. 11.

The 2D-PC cell array driving unit 402 executes the drive control of the 2D-PC cell array 202 on the basis of the emitting direction of the laser light recognized by the transmission direction recognition unit 404 and the reception direction of the reflected light recognized by the reception direction recognition unit 406, in accordance with the operation mode (LiDAR operation mode/flash LiDAR operation mode/light-section method operation mode) controlled by the CPU 408. A drive control of the beam emitted from the 2D-PC cell array 202 is executed.

The transmission direction recognition unit 404 recognizes an emitting direction of the laser light emitted from the signal transmitting unit 200 in accordance with the feedback information provided from the FBPD array 204, and provides a recognition result to the CPU 408 and the 2D-PC cell array driving unit 402. The reception direction recognition unit 406 recognizes a reception direction of the reflected light from the light receiving position on the imaging surface of the image sensor 18, and provides a recognition result to the CPU 408. The 3D image storage unit 410 stores image data captured by the image sensor 18 and provides the stored image data to distance detection unit (TOF) 412 etc.

The distance detection unit (TOF) 412 calculates a distance to the measuring object on the basis of the light receiving position on the imaging surface of the image sensor 18 and the time from light emission to light reception (arrival time), in accordance with the operation mode (LiDAR operation mode/flash LiDAR operation mode/light-section method operation mode) controlled by the CPU 408. The distance detection unit (TOF) 412 corresponds to the distance calculation unit 22 illustrated in FIG. 11.

The object recognition logic 414 identifies the measuring object on the basis of a calculation result of the distance detection unit (TOF) 412.

The MCPU 500 controls the entire main system mounted in the 3D sensing system 100 according to the embodiments. For example, when the 3D sensing system 100 is mounted in a vehicle, the MCPU 500 corresponds to a main CPU provided in the side of the vehicle.

A user interface (I/F) unit 504 is connected to the MCPU 500. The user I/F unit 504 includes: an input unit 506 for a user to input instructions (e.g., start/end of sensing processing, selecting of operation mode, and the like) to the 3D sensing system 100; and an output unit 508 for presenting sensing information detected by the 3D sensing system 100 to the user. The sensing information detected by the 3D sensing system 100 may be output as an image depicting a measuring object, and may be output as sound information, such as a warning sound.

On the basis of the image data stored and accumulated in the 3D image storage unit 410, the AI unit 502 learns the sensing result from the 3D sensing system 100, and assists more appropriately the sensing processing executed by the 3D sensing system 100.

### (Modified Example 1 of 3D Sensing System)

FIG. 22A schematically illustrates a block structural example of a 3D sensing system 100 according to a modified example 1 of the embodiments. Moreover, FIG. 22B schematically illustrates an alternative block structural example of the 3D sensing system according to the modified example 1 of the embodiments. The difference between the structure in FIG. 22A and the structure in FIG. 22B is that the signal transmitting unit 200 includes a feedback photo diode (FBPD) array 204 in FIG. 22A, while the signal transmitting unit 200 includes no FBPD array 204 in FIG. 22B. In this way, the FBPD array 204 may be included or may be omitted. Since the feedback operation can be executed also by a camera, the FBPD array 204 may be omitted.

The difference between the 3D sensing system 100 illustrated in FIG. 21A and the 3D sensing system 100 according to the modified example 1 is a point that the signal processing unit 400 includes no reception direction recognition unit 406 as illustrated in FIG. 22A.

In the 3D sensing system 100 according to the modified example 1 of the embodiments, the 2D-PC cell array driving unit 402 executes the drive control of the 2D-PC cell array 202 on the basis of the emitting direction of laser light recognized by the transmission/reception direction recognition unit 405.

The block structural example of the 3D sensing system 100 according to the modified example 1 is the same as the block structural example of the 3D sensing system 100 according to the embodiments illustrated in FIG. 21A, except for the above-mentioned difference.

### (Block Configuration of 2D-PC Cell Array Driving Unit)

FIG. 23 schematically illustrates a block structural example of the 2D-PC cell array driving unit 402 applicable to the 3D sensing system according to the embodiments.

The 2D-PC cell array driving unit 402 includes an operation selection unit 4022, a LiDAR operation control unit 4024, a flash LiDAR control unit 4026, and a structured light-section control unit 4028, as illustrated in FIG. 23.

The operation selection unit 4022 controls the LiDAR operation control unit 4024, the flash LiDAR control unit 4026, and the structured light-section control unit 4028, in accordance with the operation mode (LiDAR operation mode (M1)/flash LiDAR operation mode (M2)/light-section method operation mode (M3)) controlled by the CPU 408.

Specifically, when the operation mode is the LiDAR operation mode (M1), the LiDAR operation control unit 4024 executes the drive control of 2D-PC cell array 202 so that one laser element is driven and the twin beam (A, B) is emitted. When the operation mode is the flash LiDAR operation mode (M2), the flash LiDAR control unit 4026 executes the drive control of 2D-PC cell array 202 so that a certain region (sensing space) is irradiated with light for given length of time. When the operation mode is the light-section method operation mode (M3), the structured light-section control unit 4028 executes the drive control of 2D-PC cell array 202 so that the striped pattern light is projected onto the measuring object.

The operation selection unit 4022 executes a selection control of the three operation modes as follows, for example.

First, the flash LiDAR control unit 4026 is made to execute the drive control in accordance with the flash LiDAR operation mode (M2) (for example, a higher output of approximately several 100 W). Next, the LiDAR operation control unit 4024 is made to execute the drive control in accordance with the LiDAR operation mode (M1) (for example, an output of approximately several W to approximately several tens of W). Next, the structured light-section control unit 4028 is made to execute the drive control in accordance with the light-section method operation mode (M3).

Then, the operation selection unit 4022 may return the operation mode to the initial flash LiDAR operation mode (M2), or may terminate the processing. Moreover, the order of the processing of flash LiDAR operation mode (M2) and the processing of light-section method operation mode (M3) may be reversed. One or two operation modes of the three operation modes may also be combined with each other.

In this way, the way the three operation modes are combined can be selected arbitrarily, but in principle, the processing will not shift to the next operation mode until the sensing processing in one operation mode is completed.

### (Modified Example 2 of 3D Sensing System)

FIG. 24A schematically illustrates a block structural example of a 3D sensing system 100 according to a modified example 2 of the embodiments. Moreover, FIG. 24B schematically illustrates an alternative schematic block structural example of the 3D sensing system according to the modified example 2 of the embodiments. The difference between the structure in FIG. 24A and the structure in FIG. 24B is that the signal transmitting unit 200 includes a feedback photo diode (FBPD) array 204 in FIG. 24A, while the signal transmitting unit 200 includes no FBPD array 204 in FIG. 24B. In this way, the FBPD array 204 may be included or may be omitted. Since the feedback operation can be executed also by a camera, the FBPD array 204 may be omitted.

The difference between the 3D sensing system 100 according to the modified example 2 and the 3D sensing system 100 according to the modified example 1 (FIG. 22A) is a point that the AI unit 407 is provided in the signal processing unit 400 as illustrated in FIG. 24A.

In the 3D sensing system 100 according to the modified example 2 of the embodiments, the AI unit 407 learns a sensing result of the 3D sensing system 100 on the basis of the image data stored and accumulated in the 3D image storage unit 410, and controls more appropriately the next and subsequent sensing processing executed by 3D sensing system 100 (in particular, the transmission/reception direction recognition unit 405 and the distance detection unit (TOF) 412).

The block structural example of the 3D sensing system 100 according to the modified example 2 is the same as the block structural example of the 3D sensing system 100 according to the modified example 1 of the embodiments illustrated in FIG. 22A, except for the above-mentioned difference.

### (Modified Example 3 of 3D Sensing System)

FIG. 25 schematically illustrates a block structural example of a time-of-flight (TOF) ranging system 600, in a 3D sensing system according to a modified example 3 of the embodiments. An example of sensing in accordance with the LiDAR operation mode will now be mainly described.

The TOF ranging system 600 irradiates a measuring object 700 with laser light A, B, measures the time until reflected light RA, RB is reflected and returned, and thereby measures the distance to the measuring object 700.

The TOF ranging system 600 includes a 2D-PC cell array 202, a PWM modulation control unit 203, a phase difference detection unit 205, an image sensor 302, an optical system 304, and a distance detection unit 412. It should be noted that since the practice of the present application uses the same time measurement principle as that of the flash LiDAR, a certain amount of pulse width may be required, but an operation in which the pulse width is not changed can also be realized. Typically, in the application for such measurement, pulses of several ns to ten and several ns are repeatedly generated as short as possible. Repetition frequency is determined in accordance with the detected distance. After the reflection from the set distance of the first pulse is returned and the processing is completed, the next pulse is output.

The 2D-PC cell array 202 emits the twin beam A, B in which amplitude is modulated to the fundamental frequency (e.g., several 100 MHz) by the PWM modulation control unit 203. The emitting light A and emitting light B are reflected from the measuring object 700 and are received by image sensor 302 through the optical system 304 as the reflected light RA and reflected light RB, respectively. In this case, if there is no reflected light, it can be recognized as that no object (no measuring object) exists in the corresponding direction.

The phase difference detection unit 205 detects a phase difference in frequency between the emitting light A and emitting light B and the reflected light RA and reflected light RB, respectively.

The distance detection unit 412 includes a distance calculation circuit 4121 configured to calculate the time on the basis of the phase difference detected by the phase difference detection unit 205, and a distance data detection unit 4122 configured to detect the distance to the measuring object 700 by multiplying the time calculated by the distance calculation circuit 4121 by the light velocity.

In the LiDAR operation mode of the TOF ranging system 600 according to the modified example 3, the above distance calculation is repeatedly executed for different emitting directions.

Although not illustrated, the TOF ranging system 600 according to the modified example 3 may also include the AI unit 502, the 3D image storage unit 410, the object recognition logic 414 and/or the user I/F unit 504 including the input unit 506 and the output unit 508 illustrated in FIG. 21A or the like.

(Image Sensor applicable to 3D Sensing System (Area))

FIG. 26 schematically illustrates a block structural example of an image sensor (area) 302 applicable to the 3D sensing system according to the embodiments.

The image sensor (area) 302 is an image sensor configured to measure the distance to the measuring object by means of the TOF method and outputs a phase difference information of light emission/reception timing using PWM modulated laser light. As illustrated in FIG. 26, The image sensor (area) 302 includes a light receiving unit 3021, a vertical shift register 3022, a bias generation circuit 3023, a timing circuit 3024, a sample and hold circuit 3025, a horizontal shift register 3026, and buffer amplifiers 3027A, 3027B. A signal output from the light receiving unit 3021 is subjected to required signal processing in the sample and hold circuit 3025 and to sequential scanning in the horizontal shift register 3026, and then read out as a voltage output. Two phase signals corresponding to distance information from output terminals Vₒᵤₜ1, Vₒᵤₜ2 are output.

### (Beam Arrangement)

FIG. 27A schematically illustrates an example of arrangement of a twin beam emitted from the 2D-PC SEL cell array 10 applicable to the 3D sensing system according to the embodiments; and FIG. 27B schematically illustrates an enlarged drawing of a central beam and a beam which is adjacent thereto.

The 3D sensing system during sensing has the following functions.
(1) Two beams (twin beam) simultaneously generated are handled. Therefore, it is important to handle the emission and reception of the twin beams for sensing.
(2) In the light emission, the beam scanning plane is configured of a rotating system (point symmetry).
(3) In light reception, the reflected light from two beams scanned by the rotating system can be distinguished.
(4) Arbitrary twin beams can be simultaneously emitted.

In FIG. 27A, the diameter (resolution) of the beam in which the cone of the twin beam arrangement (scanning plane, emitting angle) 0.34° beam is arranged in consideration of the emitting angle (closest-packing of circle) is 200 m: 1.19 m, 100 m: 0.59 m, 50 m: 0.29 m, 10 m: 0.06 m.

The arrangement shown in FIG. 27B is an example of the beam arrangement, and in practice, it is necessary to consider a beam arrangement with no omission in the sensing space. As one example, closest-packing of circle to an infinite plane is used. The optimal beam arrangement is designed by controlling an overlap in these circular regions in accordance with the intensity distribution of laser beam.

FIG. 28 schematically illustrates an example of twin beam arrangement emitted from the 2D-PC SEL cell array applicable to the 3D sensing system according to the embodiments, in particular an example of a beam arrangement using a closest-packing pattern of circles. In FIG. 28, the corresponding numbers represent a pair of twin beams.

FIG. 28 illustrates an example of a beam arrangement using the closest-packing pattern of circles, and a beam spreading angle of the PC laser and the plane including the beams is designed so that the twin beam is located in a point-symmetrical position centered at the beam position 0. The beam scanning at the time of actual sensing by the 3D sensing system according to the embodiments is different from the method such as the conventional raster scan, and it is also possible to scan in completely different directions in order. If the adjacent regions are scanned, the order of beam positions can be considered, as follows: 0→1→5→8→2→11→6→4→9→13→2. . . . For example, in the case of installation in a vehicle, there is a high flexibility in controlling the system according to the driving situation, such as scanning only the center region when driving on an expressway. If beam positions 0, 1, 2, and 3 are simultaneously emitted, a line-shaped pattern is projected, and if beam positions 0, 1, 5, and 8 are emitted, the central region is illuminated.

In an example of the twin beam using the closest-packing pattern of circles emitted from the 2D-PC SEL cell array applicable to the 3D sensing system according to the embodiments, FIG. 29A illustrates an explanatory diagram of the maximum horizontal angle MHD and the maximum vertical angle MVD in a part of a spherical surface showing a sensing range; FIG. 29B illustrates an explanatory diagram showing a beam divergence angle BDA and a center position of the beam of equilateral triangle arrangement; and FIG. 29C illustrates an example of arrangement of the laser beams.

In FIG. 28, the beam arrangement for sensing is depicted as a plurality of circles in a plane for clarity, but strictly speaking, it is the intersection between a sphere with a radius of a certain distance and a cone formed of the beam, as illustrated in FIG. 29. As shown in FIG. 29B, if drawing the beam as an intersecting line with a plane at a certain distance, it will be an ellipse except for the “0^{th}” beam position, but it is not the distance in the case of the “0^{th}” beam position.

FIG. 29A illustrates a part of a spherical surface SF representing a sensing range (a spherical surface obtained by cutting a spherical surface having a radius at a certain distance from the origin O in an angular range representing a sensing range). MHD (1/2) is the maximum horizontal angle range (1/2), and MVD (1/2) is the maximum vertical angle range (1/2).

In FIG. 29B, θh is the horizontal angle, θv is the vertical angle, and BDA is the beam divergence angle. FIG. 29B illustrates an equilateral triangle arrangement (polar coordinates) showing the center position of beam, the vertex is the beam center, and one side of triangular shape corresponds to the beam divergence angle. Once the horizontal and vertical angular range is defined, the number of required beams can be calculated.

FIG. 29C illustrates a coordinate system for expressing an example of arrangement of the laser beam in terms of angle, where the length indicates an angle and does not correspond to the length in the projection plane at a certain distance. The number of beams required is provisionally calculated by defining the specific conditions as follows. Namely, the horizontal angular range: −50° to 50°, the vertical angular range: −10° to 10°, the beam divergence angle: 0.34°, the range is 238 meters horizontally and 35 meters vertically, at 100 meters away (the range is 60 meters horizontally and 9 meters vertically at 25 meters away), the horizontal number of beams: 100/0.34+1=295, the vertical number of beams: 20/(0.34×0.87)+1=69 (since there is an overlap in a vertical direction, it is shortened to horizontal sin 60°), the total number of beams: 20,355, and the total PC SEL number: 10,178.

The specification of beam of each photonic crystal surface emitting Laser (PC SEL) composing the 2D array is determined by selecting vertex pair with the origin point symmetry as shown by the corresponding number in an example of the laser beam arrangement in FIG. 29C. The spread angle of the twin beam is calculated from the length between vertices (the length of one side of the equilateral triangle corresponds to the beam divergence angle), and the rotation angle of beam is determined by angle between the line segments connecting the vertex pairs and the axis. For example, in the twin beam of No. 5, the beam spread angle is twice the beam divergence angle, and the rotation angle is 60° counterclockwise to the horizontal axis.

### (Light Receiving System)

In the 3D sensing system according to the embodiments, FIG. 30A illustrates a schematic diagram of a light receiving system (16, 18) configured to receive a reflected light R, and FIG. 30B illustrates a schematic diagram of the image sensor in FIG. 30A.

The light receiving system in the 3D sensing system according to the embodiments includes an imaging lens 16 and an image sensor (or arrayed light-receiving element) 18, and is configured to receive the reflected light R, as illustrated in FIG. 30A. The light receiving system in embodiments can distinguish reflected light from two laser beams emitted toward the central target, which is a characteristic of PC lasers. Furthermore, by utilizing the characteristics of photonic crystals, a large number of laser beams can be emitted simultaneously as illumination light to a certain region, also capable of functioning as a flash LiDAR.

### (Relationship Between Laser Light Intensity and Injection Current)

In a 3D sensing system according to a comparative example, FIGS. 31A to 31E illustrate an example in which the light intensity differs depending on the direction (position) even if the current value I equal to each cell 121, 122, 123, and 124 of the 2D-PC SEL cell array 120AR is injected. FIG. 31A illustrates the 2D-PC SEL cell array 120AR and each cell 121, 122, 123, and 124, and schematically illustrates an aspect of radiation of the beam BM when injecting the equal current value I into each cell 121, 122, 123, and 124. FIG. 31B schematically illustrates an aspect of FFP when the beam BM radiation angle θ=0 degree, FIG. 31C schematically illustrates an aspect of FFP when θ=20 degrees, FIG. 31D schematically illustrates an aspect of FFP when θ=40 degrees, and FIG. 31E schematically illustrates an aspect of FFP when θ=60 degrees.

As illustrated in the comparative example in FIGS. 31A to 31E, for example, even if the same current I is injected into each cell 121, 122, 123, 124 of the 2D-PC SEL cell array 120AR, the light intensity L may be different from each other depending on the angle θ.

On the other hand, in the 3D sensing system according to the embodiments, FIGS. 32A to 32E illustrate an example in which the light intensity is uniformed even depending on the direction (position) by injecting different current values I1, I2, I3, and I4 respectively to the cells 121, 122, 123, and 124 of the 2D-PC SEL cell array 120AR. FIG. 32A illustrates the 2D-PC SEL cell array 120AR and each cell 121, 122, 123, and 124, and schematically illustrates an aspect of radiation of the beam BM when injecting the different current values I1, I2, I3, and I4 respectively into the cells 121, 122, 123, and 124. FIG. 32B schematically illustrates an aspect of FFP when the beam BM radiation angle θ=0 degree, FIG. 32C schematically illustrates an aspect of FFP when θ=20 degrees, FIG. 32D schematically illustrates an aspect of FFP when θ=40 degrees, and FIG. 32E schematically illustrates an aspect of FFP when θ=60 degrees.

As illustrated in FIGS. 32A to 32E, the variation in the light intensity in the 2D-PC SEL cell array 120AR is detected, and the drive control of the 2D-PC SEL cell array 120AR is executed so that the respective different current values I1, I2, I3, and I4 are injected to the respective cells 121, 122, 123, and 124 of the 2D-PC SEL cell array 120AR, and thereby the light intensity can be uniformed. For example, by configuring the feedback control mechanism as illustrated in FIG. 7, the variation in the light intensity in the 2D-PC SEL cell array 120AR can be detected on the basis of the feedback laser light C (FB).

### (Emitting Beam Control of 2D-PC SEL Cell Array)

In an example of emitting beam control of the 2D-PC SEL cell array 120AR applicable to the 3D sensing system according to the embodiments, FIG. 33A illustrates a state where a lattice 212A for forming optical resonance state and a lattice 212B for light-emitting are arranged in one cell, FIG. 33B illustrates a schematic top view diagram of the one cell, and FIG. 33C illustrates a structural example of an electrode arrangement for realizing uniaxial scanning.

The example of the arrangement state of the lattice 212A for forming optical resonance state and the lattice 212B for light-emitting illustrated in FIG. 33A corresponds to the example of the arrangement state illustrated in FIG. 5, and the laser beam is emitted in the direction where the parameter (r₁, r₂), which indicates the position of the lattice point, satisfies the equations (1) and (2) previously shown.

As illustrated in FIG. 33C, the parameter (r₁, r₂), which indicates the position of the lattice point toward the electrodes E1 to E4, is continuously changed. For example, when the current is flowed only through the electrode E2, the beam is emitted in the direction of (θ, φ)=(20, 0). The current balance provided to the adjacent electrode (E1 to E4) allows for continuous angular swing.

In an example of emitting beam control of the 2D-PC SEL cell array 120AR applicable to the 3D sensing system according to the embodiments, FIG. 34A illustrates a relationship between r₁, r₂ and the angle θ, and FIG. 34B illustrates an alternative structural example of the electrode arrangement for realizing uniaxial scanning. Also, in FIG. 34B, r₁ and r₂ are also continuously changed over electrodes E1 to E4. The scanning is executed in the uniaxial direction illustrated in FIG. 34B.

In an example of emitting beam control of the 2D-PC SEL cell array 120AR applicable to the 3D sensing system according to the embodiments, FIG. 35A illustrates a structural example of an electrode arrangement for realizing biaxial scanning, and FIG. 35B illustrates a schematic diagram of scanning directions. The scanning is executed in biaxial directions (SV1, SV2, and SH1, SH2) illustrated in FIG. 35B.

In an example of emitting beam control of the 2D-PC SEL cell array 120AR applicable to the 3D sensing system according to the embodiments, FIG. 36A illustrates a structural example of an electrode arrangement for realizing rotational scanning, and FIG. 36B illustrates a schematic diagram of scanning directions. The rotational scanning is executed in the scanning directions (SV1, SV2, SC, and SH1, SH3) illustrated in FIG. 36B.

### (Strip-Shaped Electrode Arrangement)

In the 2D-PC SEL cell applicable to the 3D sensing system according to the embodiments, FIG. 37A illustrates a top view diagram illustrating a state where a lattice 212A for forming optical resonance state is arranged as a lattice point where a hole (different refractive index region) is arranged at a 2D-PC layer; FIG. 37B illustrates a top view diagram illustrating a state where a lattice 212B for light-emitting is arranged; FIG. 37C illustrates a top view diagram illustrating a state where strip-shaped upper electrodes 252 are arranged; and FIG. 37D illustrates a top view diagram illustrating an alternative state where the strip-shaped upper electrodes 252 are arranged.

Herein, strip-shaped electrodes E1 to E19 described below are used as the lower electrode, instead of lower electrode not illustrated in FIG. 1 or 2. Other than that, the configuration of the PC laser is the same as the configuration of the PC laser illustrated in FIGS. 1, 2, and the like.

The 2D-PC layer illustrated in FIG. 37 is obtained by arranging a hole (different refractive index region) on each lattice point of lattice (not shown) formed by combining and superposing the lattice 212A for forming optical resonance state (FIG. 37A) and the lattice 212B for light-emitting (FIG. 37B). The lattice 212A for forming optical resonance state is a square lattice of the lattice constant a. In the lattice 212B for light-emitting, the lattice points are arranged at interval a in the y direction, and the lattices 212B for light-emitting are arranged at different intervals for each of a plurality of the virtually divided regions 66 (it is referred to as different period region. This is different from the different refractive index region) in the x direction.

Strip-shaped electrodes (E1 to E5), (E6 to E12), and (E13 to E19) are provided on an upper surface of the upper substrate 242 as the upper electrode 252, as illustrated in FIG. 37C. These strip-shaped electrodes (E1 to E5), (E6 to E12), and (E13 to E19) are many electrodes having the width in the x direction is narrower than the width of the different period region 66 are arranged in the X direction (FIG. 37C).

FIG. 37D illustrates a state where the strip-shaped electrodes (E1, E3, E5), (E7, E10), and (E13, E16, E19) are arranged in the x direction.

In the PC laser illustrated in FIG. 37, the current is injected into the active layer 222 from only electrodes that are directly above and/or below one different period region 66 of the many electrodes E1 to E19 provided as the upper electrode 252. As a result, light in a wavelength region which includes a light of a predetermined wavelength thus in an active layer 222 which is directly below the different period region 66 is emitted, the light of the predetermined wavelength causes resonance in the different period region 66, and an inclined beam is emitted. Herein, the structure of lattice 212B for light-emitting is different for each different period region 66. Accordingly, by switching the different period region 66 where the light causes resonance, i.e., by switching the individual electrodes of the strip-shaped electrodes E1 to E19 where the current is injected, the laser oscillation position can be gradually changed and the beam inclined angle can be continuously changed.

The 2D-PC SEL array and the image sensor, and the drive and control of the 2D-PC SEL array and image sensor have been described above, and the support for multiple operation modes including flash has also been described above.

In the case of a system that always uses fixedly the flash operation for the entire surface of a specific region, a dedicated flash light source such as a laser or LED can be used in addition to the PC SEL array, as another aspect of the embodiments. The details will now be described hereinafter.

### (3D Sensing System by Operation Mode in Combination of Flash Operation Mode and LiDAR Operation Mode)

FIG. 38 illustrates a conceptual diagram of an operation mode in combination of the flash operation mode and the LiDAR operation mode (it is also referred to merely “combination operation mode”), in the 3D sensing system according to the embodiments.

The 3D sensing system in the combination operation mode according to the embodiments includes a flash (FL) light source 250 for entire surface irradiation as a light source, and a 2D-PC SEL cell array 202 for irradiation of a target region.

The FL source 250 emits laser light FL to the entire surface of a specific region (sensing region). In an example illustrated in FIG. 38, three measuring objects, i.e., a vehicle VH, a vehicle VB, and a pedestrian (person) HM exist in a region.

Reflected light RVH, RVB, RHM emitted from the FL source 250 and reflected from the measuring objects VH, VB, HM by a time-of-flight (TOF) camera 350, to measure the distance to each measuring object VH, VB, HM.

At this time, for example, the body color of vehicle VH and the clothing color of the pedestrian HM are relatively bright (e.g., white based, yellow based, etc.), and the body color of vehicle VB is relatively dark (e.g., black based, dark blue based, brown based, etc.). Accordingly, since the reflectance of the vehicle VH and the pedestrian HM having relatively bright color is relatively high and the signal to noise (S/N) ratio thereof is also high, the TOF camera 350 can observe the vehicle VH and the pedestrian HM. However, since the reflectance of the vehicle VB having relatively dark color is relatively low and the S/N ratio thereof is also low, it is difficult for the TOF camera 350 to observe the vehicle VB.

Therefore, only in the target region of the measuring object (in this case, the vehicle VB) having low reflectance and insufficient S/N ratio is irradiated with a spot beam from the 2D-PC SEL cell array 202, and then the reflected light is observed. As a result, it enables measurement of the distance with high sensitivity, even for measurement objects such as the vehicle VB.

### COMPARATIVE EXAMPLES

An operation flow of a flash LiDAR system according to a comparative example will now be described, with reference to FIG. 39. The flash LiDAR system according to the comparative example uses only the flash LiDAR operation mode in the 3D sensing system illustrated in FIG. 38.

In Step S400, the entire surface of the specific region is irradiated with laser light FL from the FL source 250.

Next, in Step S401, the reflected light RVH, RVB, RHM emitted from the FL source 250 and respectively reflected from the measuring objects VH, VB, HM is observed by the TOF camera 350. In this case, if there is no reflected light, it can be recognized as that no object (no measuring object) exists in the corresponding direction.

Next, in Step S402, it is determined whether or not there is any region where the S/N of the reflected light is lower than a predetermined threshold value T. A result of the determination in Step S402, if there is no region where the S/N of the reflected light is lower than the predetermined threshold value T (in the case of NO in Step S402), a distance image (3D image) is output in Step S403.

In contrast, as a result of the determination in Step S402, if there is any region where the S/N of the reflected light is lower than the predetermined threshold value T (in the case of YES in Step S402), a distance image to be obtained by calculating the distance of the region cannot be output. Accordingly, in Step S404, the irradiation intensity from the FL source 250 is increased, and the entire surface of a specific region is irradiated with the laser light FL again.

Next, in Step S405, the reflected light emitted from the FL source 250 and reflected from the measuring object is observed by the TOF camera 350. However, a region other than a region where the S/N ratio is lower than the predetermined threshold value T is saturated by the noise, and therefore a distance image cannot be output. In this way, if a measuring object having low reflectance is included, distance measurement becomes difficult due to reduction of the S/N ratio.

### (Operation Flow of 3D Sensing System in Combination Operation Mode)

An operation flow of the 3D sensing system illustrated in FIG. 38 will now be described, with reference to FIG. 40.

In Step S500, the entire surface of the specific region is irradiated with laser light FL from the FL source 250 (flash type).

Next, in Step S501, the reflected light RVH, RVB, RHM emitted from the FL source 250 and respectively reflected from the measuring objects VH, VB, HM is observed by the TOF camera 350.

In this case, if there is no reflected light, it can be recognized as that no object (no measuring object) exists in the corresponding direction.

Next, in Step S502, it is determined whether or not there is any region where the S/N of the reflected light is lower than the predetermined threshold value T. A result of the determination in Step S502, if there is no region where the S/N of the reflected light is lower than the predetermined threshold value T (in the case of NO in Step S502), a distance image (3D image) is output in Step S503.

In contrast, as a result of the determination in Step S502, if there is any region where the S/N of the reflected light is lower than the predetermined threshold value T (in the case of YES in Step S502), e.g., in the case of the vehicle VB having a relatively low reflectance and a relatively low S/N ratio, a distance image to be obtained by calculating the distance of the region cannot be output. Therefore, in Step S504, only a region where the S/N ratio is lower than the predetermined threshold value T is irradiated with a spot beam from the 2D-PC SEL cell array 202 (beam scanning type).

Next, in Step S505, the reflected light emitted from the 2D-PC SEL cell array 202 and reflected from the measuring object is observed by the TOF camera 350, and it is determined in Step S506 whether or not there is any region where the S/N ratio of the reflected light is lower than the predetermined threshold value T.

the S/N of the reflected light is lower than the predetermined threshold value T (in the case of NO in Step S506), a distance image (3D image) is output in Step S507.

In contrast, as a result of the determination in Step S506, if there is any region where the S/N of the reflected light is lower than the predetermined threshold value T (in the case of YES in Step S506) although it is assumed that there is some kind of measuring object, a distance image to be obtained by calculating the distance of the region cannot be output.

Therefore, in Step S508, the light intensity to be emitted from the 2D-PC cell array 202 is increased, then returning to Step S504, only the region concerned is irradiated with a spot beam from the 2D-PC SEL cell array 202. Herein, as an adjustment method for increasing the light intensity in step S508, for example, a method for increasing a voltage supplied to the 2D-PC SEL cell array 202 can be applied.

Then, until there is no more region where the S/N ratio of the reflected light is lower than the predetermined threshold T, i.e., until all the measurement objects in the region are detected, the processing of steps S504 to S508 is repeated.

In this way, by introducing the operation mode in combination of the flash operation mode and the LiDAR operation mode in the 3D sensing system according to the embodiments, even when a measuring object having low reflectance is included in a sensing region, the distance of the measuring object having low reflectance can be measured.

It is configured so that, first, the entire surface of the specific region is irradiated with the laser light FL from the FL source 250 beforehand, and the measuring object included to the specific entire region is detected (flash operation mode), and then only the measuring object which cannot be detected at that time is irradiated with the spot beam from the 2D-PC SEL cell array 202 to be detected (LiDAR operation mode). Accordingly, the processing can be executed more efficiently than operating in the LiDAR operation mode from the beginning to the end.

### (Modulated PC Laser Light Source for Irradiation to Target Region)

FIG. 41 schematically illustrates a sectional diagram of an example of an irradiation pattern, as an example of a PC laser light source for entire surface irradiation, in the 3D sensing system according to the embodiments. FIG. 42 schematically illustrates a diagram of an illuminating surface of an example of the irradiation pattern, as an example of the PC laser light source for entire surface irradiation, in the 3D sensing system according to the embodiments.

FIGS. 41 and 42 illustrate an example of the modulated PC laser light source (2D-PC SEL cell array 202) for irradiation to a target region in spot, in the 3D sensing system according to the embodiments. The PC laser light source for irradiation to target region (2D-PC SEL cell array 202) irradiates a specified position (e.g., position for irradiation to target region in FIG. 42) within a range of ±60° of the horizontal direction and ±60° of the vertical direction, with laser light, for example. One of the twin beams, e.g., the beam B, emitted from the modulated PC laser source for irradiation to target region is used, but both beams A and B may be used.

The emitting angle is, for example, approximately 2° per one point in a specified direction, which is approximately ±60° in the horizontal direction and ±60° in the vertical direction for the entire array.

The output is more than approximately 0.2 W per one point, for example. By arranging a plurality of light sources B, it is possible to increase the output, but when the pulse width is long or the repetition frequency is high, an ingenuity of heat dissipation may be required.

### (PC Laser Light Source for Entire Surface Irradiation)

FIG. 41 schematically illustrates a sectional diagram of an example of an irradiation pattern, as an example of a PC laser light source (FL source 250) for entire surface irradiation, in the 3D sensing system according to the embodiments. FIG. 42 schematically illustrates a diagram of an illuminating surface of an example of the irradiation pattern, as an example of the PC laser light source (FL source 250) for entire surface irradiation, in the 3D sensing system according to the embodiments.

The laser used as the FL source 250 is, for example, surface-vertical type PC SEL or VCSEL, emitted laser light is appropriately spread by a lens or a diffuser, and irradiates a range of ±60°. The lens used herein is, for example, ball lens, a Graded Index (GI) lens, or a lens obtained by combining a plurality of lenses. More expansively, irradiation within a range of ±60° can be realized, without using lenses or diffusers.

The PC laser light source for entire surface irradiation is an entire surface irradiation type, for example, within a range of ±60° in the horizontal direction and ±60° in the vertical direction, and irradiates the entire surface of the sensing region with laser light FL by spreading the light emission of a single element. The emitting angle is, for example, approximately 2° per a single element, and more expansively, it uniformly irradiates within a range of approximately ±60° in the horizontal direction and approximately ±60° in the vertical direction.

The output is more than approximately 5 W, for example. When the pulse width is long or the repetition frequency is high, an ingenuity of heat dissipation may be required. The package to be used therefor is a 5.6 mm φ stem, for example.

### (Block Configuration of 3D Sensing System in Combination Operation Mode)

FIG. 43A schematically illustrates a block configuration in the combination operation mode of the flash operation mode and the LiDAR operation mode, in the 3D sensing system in the combination operation mode according to the embodiments. The identical or similar reference sign is attached to the identical or similar block configuration as illustrated in FIG. 21A, and the description thereof is omitted or simplified.

FIG. 43A illustrates a schematic block configuration diagram of the operation mode realized by combining the flash operation mode and the LiDAR operation mode, in the 3D sensing system according to the embodiments. FIG. 43B illustrates an alternatively schematic block configuration diagram of the operation mode realized by combining the flash operation mode and the LiDAR operation mode, in the 3D sensing system according to the embodiments. The difference between the structure in FIG. 43A and the structure in FIG. 43B is that the signal transmitting unit 200 includes a feedback photo diode (FBPD) array 204 in FIG. 43A, while the signal transmitting unit 200 includes no FBPD array 204 in FIG. 43B. In this way, the FBPD array 204 may be included or may be omitted. Since the feedback operation can be executed also by a camera, the FBPD array 204 may be omitted.

As illustrated in FIG. 43A, the 3D sensing system 100 according to the embodiments includes: a flash light source 250 for entire surface irradiation configured to emit laser light to an entire surface of a specific region (sensing region); a 2D-PC SEL cell array 202 configured to emit laser light to a target region of the specific region; a control unit (CPU) 408 configured to control an operation mode of the laser light source (202, 250); a flash driving unit 415 for executing a drive control of the flash light source 250 and a 2D-PC cell array driving unit 402 configured to execute a drive control of the 2D-PC SEL cell array 202, in accordance with the operation mode controlled by the control unit 408; a signal receiving unit 300 configured to receive the laser light emitted from the flash light source 250 and reflected from a measuring object included in the specific region, as a reflected light, and to receive the laser light emitted from the 2D-PC SEL cell array 202 reflected from a measuring object included in a target region, as a reflected light; a signal processing unit 400 configured to execute signal processing of the reflected light received by the signal receiving unit 300 in accordance with the operation mode; and a distance detection unit 412 configured to execute calculation processing of the distance to the measuring object with respect to the signal processed by the signal processing unit 400 in accordance with the operation mode.

The signal processing unit 400 determines whether or not there is any region where the S/N ratio of the reflected light emitted from the flash light source 250 and reflected is lower than the predetermined threshold value in the specific region. When there is a region where the S/N ratio is lower than the predetermined threshold value, the signal processing unit 400 controls the 2D-PC cell array driving unit 402 so as to irradiate only the region where the S/N ratio is lower than the predetermined threshold value as a target with spot laser light from the 2D-PC SEL cell array 202.

Moreover, the signal processing unit 400 determines whether or not there is any region where the S/N ratio of the spot reflected light emitted from the 2D-PC SEL cell array 202 and reflected is lower than the predetermined threshold value T. As a result of the determination, when there is a region where the S/N ratio is lower than the predetermined threshold value T, the signal processing unit 400 controls the 2D-PC cell array driving unit 402 to increase the light intensity emitted from the 2D-PC SEL cell array 202 and then to irradiate only targeting the region concerned with the spot laser light from the 2D-PC SEL cell array 202.

In this case, there are the flash operation mode and the LiDAR operation mode as the operation mode, the flash driving unit 415 executes the drive control of the flash light source 250 when the operation mode is the flash operation mode, and the 2D-PC cell array driving unit 402 executes the drive control of the 2D-PC SEL cell array 202 when the operation mode is the LiDAR operation mode.

The 3D sensing system 100 according to the embodiments will now be described in more detail.

The 3D sensing system 100 according to the embodiments includes a signal transmitting unit 200, a signal receiving unit 300, and a signal processing unit 400, as illustrated in FIG. 43A.

The signal transmitting unit 200 includes: a flash (FL) light source 250 for entire surface irradiation configured to emit laser light FL to the entire surface of a specific region, and a 2D-PC SEL cell array 202 configured to emit laser light to a target region in the specific region.

The signal receiving unit 300 includes an optical system 304 and an image sensor (line/area) 302 configured to receive a reflected light emitted from the signal transmitting unit 200 and reflected from the measuring object.

The signal processing unit 400 includes: a control unit (CPU) 408 configured to control an operation mode of the laser light source; a transmission direction recognition unit 404 configured to recognize an emitting direction of the laser light emitted from the 2D-PC SEL cell array 202; a 2D-PC cell array driving unit 402 configured to executes a drive control of the 2D-PC SEL cell array 202 in accordance with the operation mode controlled by the CPU 408 on the basis of the emitting direction of laser light recognized by the transmission direction recognition unit 404; an FL driving unit 415 configured to execute a drive control of the FL source 250; and a distance detection unit (TOF) 412 configured to calculate the distance to the measuring object on the basis of a light receiving position on an imaging surface of the image sensor 18 and the time from light emission to light reception, in accordance with the operation mode controlled by the CPU 408.

The FL source 250 first emits laser light FL to the entire surface of the specific region. The reflected light emitted from the FL source 250 and reflected from the measuring object is received in the signal receiving unit 300, and the distance to the measuring object is measured by the distance detection unit 412 in the signal processing unit 400.

At this time, the signal processing unit 400 determines whether or not there is any region where the S/N ratio of the reflected light is lower than the predetermined threshold value T. As a result of the determination, when there is no region where the S/N ratio of the reflected light is lower than the predetermined threshold value T, a distance image is output. In contrast, when there is a region where the S/N ratio is lower than the predetermined threshold value, the signal processing unit 400 controls the 2D-PC cell array driving unit 402 so as to irradiate only the targeting region where the S/N ratio is lower than the predetermined threshold value with spot beam from the 2D-PC SEL cell array 202.

The reflected light emitted from the 2D-PC SEL cell array 202 and reflected from the measuring object is received in the signal receiving unit 300. The signal processing unit 400 determines whether or not there is any region where the S/N ratio of the reflected light is lower than the predetermined threshold value T. As a result of the determination, when there is no region where the S/N ratio of the reflected light is lower than the predetermined threshold value T, a distance image is output. In contrast, when there is a region where the S/N ratio of the reflected light is lower than the predetermined threshold value T, the signal processing unit 400 controls the 2D-PC cell array driving unit 402 to increase the light intensity emitted from the 2D-PC SEL cell array 202 and then to irradiate only targeting the region concerned with the spot beam from the 2D-PC SEL cell array 202.

The signal transmitting unit 200 further includes the FBPD array 204 configured to execute a feedback control of the emitted laser light, and the transmission direction recognition unit 404 recognizes an emitting direction of the laser light emitted from the signal transmitting unit 200 in accordance with feedback information provided from the FBPD array 204.

The signal transmitting unit 200 may also include a reception direction recognition unit 406 configured to recognize a reception direction of the reflected light from the light receiving position on the imaging surface of the image sensor 18, and the 2D-PC cell array driving unit 402 executes a drive control of the 2D-PC cell array 202 on the basis of the emitting direction of the laser light recognized by the transmission direction recognition unit 404 and the reception direction of the reflected light recognized by the reception direction recognition unit 406.

The signal processing unit 400 further includes an object recognition logic 414 configured to identify the measuring object on the basis of a calculation result of the distance detection unit (TOF) 412.

The 3D sensing system 100 according to the embodiments is provided with a signal transmitting unit 200, a signal receiving unit 300, a signal processing unit 400, a main controlling unit (MCPU) 500, and an artificial intelligence (A.I. Artificial Intelligence) unit 502 so that it may illustrate to FIG. 43A.

The signal transmitting unit 200 includes: a FL source 250 for entire surface irradiation configured to emit laser light FL to the entire surface of the specific region; a 2D-PC SEL cell array 202 configured to emit laser light to the measuring object; and an FBPD array 204 configured to execute a feedback control of the emitted laser light. The FBPD array 204 corresponds to the PD 118PD illustrated in FIG. 6 or the 2D-PC 118PDAR illustrated in FIG. 8.

The signal receiving unit 300 includes an optical system 304 and an image sensor (line/area) 302 configured to receive a scattered reflected light emitted from the signal transmitting unit 200 and reflected from the measuring object.

The signal processing unit 400 includes a 2D-PC cell array driving unit 402, a transmission direction recognition unit 404, a reception direction recognition unit 406, a CPU 408, a 3D image storage unit 410, a distance detection unit (TOF) 412, and an object recognition logic 414. The CPU 408 executes an operation control of each unit on the basis of three operation modes (i.e., LiDAR operation mode, flash LiDAR operation mode, light-section method operation mode). The CPU 408 corresponds to the control unit 14 illustrated in FIG. 11.

The 2D-PC cell array driving unit 402 executes a drive control of the 2D-PC SEL cell array 202 on the basis of the emitting direction of the laser light recognized by the transmission direction recognition unit 404 and the reception direction of the reflected light recognized by the reception direction recognition unit 406, in accordance with the operation mode (LiDAR operation mode/flash LiDAR operation mode/light-section method operation mode) controlled by the CPU 408. The FL driving unit 415 executes a drive control of the FL source 250.

The transmission direction recognition unit 404 recognizes an emitting direction of the laser light emitted from the signal transmitting unit 200 in accordance with the feedback information provided from the FBPD array 204, and provides a recognition result to the CPU 408 and the 2D-PC cell array driving unit 402 and the FL driving unit 415. The reception direction recognition unit 406 recognizes a reception direction of the reflected light from the light receiving position on the imaging surface of the image sensor 18, and provides a recognition result to the CPU 408. The 3D image storage unit 410 stores image data captured by the image sensor 18 and provides the stored image data to distance detection unit (TOF) 412 etc.

The distance detection unit (TOF) 412 calculates a distance to the measuring object on the basis of the light receiving position on the imaging surface of the image sensor 18 and the time from light emission to light reception (arrival time), in accordance with the operation mode (LiDAR operation mode/flash LiDAR operation mode/light-section method operation mode) controlled by the CPU 408. The distance detection unit (TOF) 412 corresponds to the distance calculation unit 22 illustrated in FIG. 11.

The object recognition logic 414 identifies the measuring object on the basis of a calculation result of the distance detection unit (TOF) 412.

The MCPU 500 controls the entire main system mounted in the 3D sensing system 100 according to the embodiments. For example, when the 3D sensing system 100 is mounted in a vehicle, the MCPU 500 corresponds to a main CPU provided in the side of the vehicle.

A user interface (I/F) unit 504 is connected to the MCPU 500. The user I/F unit 504 includes: an input unit 506 for a user to input instructions (e.g., start/end of sensing processing, selecting of operation mode, and the like) to the 3D sensing system 100; and an output unit 508 for presenting sensing information detected by the 3D sensing system 100 to the user. The sensing information detected by the 3D sensing system 100 may be output as an image depicting a measuring object, and may be output as sound information, such as a warning sound.

On the basis of the image data stored and accumulated in the 3D image storage unit 410, the AI unit 502 learns the sensing result from the 3D sensing system 100, and assists more appropriately the sensing processing executed by the 3D sensing system 100.

### (Modified Example 4 of 3D Sensing System in Combination Operation Mode)

FIG. 44A illustrates a schematic block configuration diagram of the operation mode realized by combining the flash operation mode and the LiDAR operation mode, in a 3D sensing system according to a modified example 4 of the embodiments. FIG. 44B illustrates an alternatively schematic block configuration diagram of the operation mode realized by combining the flash operation mode and the LiDAR operation mode, in the 3D sensing system according to the modified example 4 of the embodiments. The difference between the structure in FIG. 44A and the structure in FIG. 44B is that the signal transmitting unit 200 includes a feedback photo diode (FBPD) array 204 in FIG. 44A, while the signal transmitting unit 200 includes no FBPD array 204 in FIG. 44B. In this way, the FBPD array 204 may be included or may be omitted. Since the feedback operation can be executed also by a camera, the FBPD array 204 may be omitted.

The difference between the 3D sensing system 100 according to the modified example 4 and the 3D sensing system 100 illustrated in FIG. 43A is a point that the signal processing unit 400 includes no reception direction recognition unit 406.

In the 3D sensing system 100 according to the modified example 4 of the embodiments, the 2D-PC cell array driving unit 402 executes the drive control of the 2D-PC SEL cell array 202 on the basis of the emitting direction of laser light recognized by the transmission/reception direction recognition unit 405.

The block structural example of the 3D sensing system 100 according to the modified example 4 is the same as the block structural example of the 3D sensing system 100 according to the embodiments illustrated in FIG. 43A, except for the above-mentioned difference.

### (Block Configuration of 2D-PC Cell Array Driving Unit and FL Driving Unit)

FIG. 45 schematically illustrates a block structural example of the 2D-PC cell array driving unit 402 and the FL driving unit 415 applicable to the 3D sensing system according to the embodiments. The identical or similar reference sign is attached to the identical or similar block configuration as illustrated in FIG. 23, and the description thereof is omitted or simplified.

As well as FIG. 23, the 2D-PC cell array driving unit 402 includes an operation selection unit 4022, a LiDAR operation control unit 4024, a flash LiDAR control unit 4026, and a structured light-section control unit 4028, and is configured to execute a drive control of the 2D-PC cell array 202 in accordance with the control by the CPU 408.

The FL driving unit 415 executes a drive control of the FL source 250 in accordance with the control by the CPU 408.

### (Modified Example 5 of 3D Sensing System in Combination Operation Mode)

FIG. 46A illustrates a schematic block configuration diagram of the operation mode realized by combining the flash operation mode and the LiDAR operation mode, in a 3D sensing system according to a modified example 5 of the embodiments. FIG. 46B illustrates an alternatively schematic block configuration diagram of the operation mode realized by combining the flash operation mode and the LiDAR operation mode, in the 3D sensing system according to the modified example 5 of the embodiments. The difference between the structure in FIG. 46A and the structure in FIG. 46B is that the signal transmitting unit 200 includes a feedback photo diode (FBPD) array 204 in FIG. 46A, while the signal transmitting unit 200 includes no FBPD array 204 in FIG. 46B. In this way, the FBPD array 204 may be included or may be omitted. Since the feedback operation can be executed also by a camera, the FBPD array 204 may be omitted.

The difference between the 3D sensing system 100 according to the modified example 5 and the 3D sensing system 100 according to the modified example 4 (FIG. 44A) is a point that the AI unit 407 is provided in the signal processing unit 400.

In the 3D sensing system 100 according to the modified example 5 of the embodiments, the AI unit 407 learns a sensing result of the 3D sensing system 100 on the basis of the image data stored and accumulated in the 3D image storage unit 410, and controls more appropriately the next and subsequent sensing processing executed by 3D sensing system 100 (in particular, the transmission/reception direction recognition unit 405 and the distance detection unit (TOF) 412).

The block structural example of the 3D sensing system 100 according to the modified example 5 is the same as the block structural example of the 3D sensing system 100 according to the modified example 4 of the embodiments illustrated in FIG. 44A, except for the above-mentioned difference.

### (Modified Example 6 of 3D Sensing System in Combination Operation Mode)

FIG. 47 schematically illustrates a block structural example of a time-of-flight (TOF) ranging system 600, in a 3D sensing system in a combination operation mode according to a modified example 6 of the embodiments. An example of sensing in accordance with the LiDAR operation mode will now be mainly described.

In the flash operation mode, the TOF ranging system 600 irradiates a measuring object 700 with laser light FL, measures the time until reflected light is reflected and returned, and thereby measures the distance to the measuring object 700. In the LiDAR operation mode, the TOF ranging system 600 irradiates a measuring object 700 with laser light A, B, measures the time until reflected light RA, RB is reflected and returned, and thereby measures the distance to the measuring object 700.

The TOF ranging system 600 includes an FL light source 250, a 2D-PC cell array 202, a PWM modulation control unit 203, a phase difference detection unit 205, an image sensor 302, an optical system 304, and a distance detection unit 412. It should be noted that, in the LiDAR operation mode, since the practice of the present application uses the same time measurement principle as that of the flash LiDAR, a certain amount of pulse width may be required, but an operation in which the pulse width is not changed can also be realized. Typically, in the application for such measurement, pulses of several ns to ten and several ns are repeatedly generated as short as possible. Repetition frequency is determined in accordance with the detected distance. After the reflection from the set distance of the first pulse is returned and the processing is completed, the next pulse is output.

In the LiDAR operation mode, the 2D-PC SEL cell array 202 emits the twin beam A, B in which amplitude is modulated to the fundamental frequency (e.g., several 100 MHz) by the PWM modulation control unit 203. The emitting light A and emitting light B are reflected from the measuring object 700 and are received by image sensor 302 through the optical system 304 as the reflected light RA and reflected light RB, respectively. In this case, if there is no reflected light, it can be recognized as that no object (no measuring object) exists in the corresponding direction.

The phase difference detection unit 205 detects a phase difference in frequency between the emitting light A and emitting light B and the reflected light RA and reflected light RB, respectively.

The distance detection unit 412 includes a distance calculation circuit 4121 configured to calculate the time on the basis of the phase difference detected by the phase difference detection unit 205, and a distance data detection unit 4122 configured to detect the distance to the measuring object 700 by multiplying the time calculated by the distance calculation circuit 4121 by the light velocity.

In the LiDAR operation mode of the TOF ranging system 600 according to the modified example 6, the above distance calculation is repeatedly executed for different emitting directions.

Although not illustrated, the TOF ranging system 600 according to the modified example 6 may also include the AI unit 502, the 3D image storage unit 410, the object recognition logic 414 and/or the user I/F unit 504 including the input unit 506 and the output unit 508 illustrated in FIG. 21A or the like.

As described above, according to the embodiments, there can be provided the 3D sensing system, having higher accuracy, higher output, miniaturization, and robustness, as well as higher adaptability to sensing regions and sensing objects, and capable of supporting a plurality of sensing modes.

### [Other Embodiments]

The present embodiments have been described by the embodiments, as a disclosure including associated description and drawings to be construed as illustrative, not restrictive. This disclosure makes clear a variety of alternative embodiments, working examples, and operational techniques for those skilled in the art.

Such being the case, the embodiments cover a variety of embodiments, whether described or not.

### INDUSTRIAL APPLICABILITY

The 3D sensing system according to the embodiments is available, for example, as sensing technology for assisting safe driving of vehicles, such as an in-vehicle sensor configured to detect the distance to and the shape of measuring objects existing around the vehicles; and is further available also as sensing technology for realizing advanced automatic driving systems. Moreover, it is applicable not only to vehicles but also to aircrafts, satellites, spacecraft, ships, etc. Furthermore, it is also applicable to a wide range of fields, including geology, seismology, and oceanography.

What is claimed is:

1. A three-dimensional sensing system comprising:
a photonic crystal laser array in which a photonic crystal laser element is arranged on a plane;
a control unit configured to control an operation mode of a laser light source;
a driving unit configured to execute a drive control of the photonic crystal laser array in accordance with the operation mode controlled by the control unit;
a light receiving unit configured to receive reflected light that is laser light emitted from the photonic crystal laser array reflected from a measuring object;
a signal processing unit configured to execute signal processing of the reflected light received by the signal receiving unit in accordance with the operation mode; and
a distance calculation unit configured to execute calculation processing of a distance to the measuring object with respect to a signal processed by the signal processing unit, in accordance with the operation mode, and to output a calculation result as distance data.

2. The three-dimensional sensing system according to claim 1, further comprising:
a transparent electrode or a DBR layer passing through a feedback laser light; and
a photo diode configured to detect the feedback laser light, wherein
the driving unit detects a variation in light intensity in the photonic crystal laser array on the basis of the feedback laser light, and executes a drive control so that an injection current is changed for each cell of the photonic crystal laser array.

3. The three-dimensional sensing system according to claim 1, wherein
the light receiving unit comprises an imaging lens and an image sensor, wherein
the distance calculation unit calculates the distance to the measuring object on the basis of a light receiving position on an imaging surface of the image sensor and a time from light emission to light reception of the laser light emitted from the photonic crystal laser array, in accordance with the operation mode controlled by the control unit, and outputs a calculation result is as distance data.

4. The three-dimensional sensing system according to claim 3, wherein
the operation mode comprises a LiDAR operation mode, a flash LiDAR operation mode, and a light-section method operation mode.

5. The three-dimensional sensing system according to claim 4, wherein
when the operation mode is the LiDAR operation mode, the driving unit executes the drive control of the photonic crystal laser array so that a twin beam is emitted from one element of the photonic crystal laser array.

6. The three-dimensional sensing system according to claim 5, wherein
the distance calculation unit determines which beam of the emitted light is the reflected light on the basis of the light receiving position on the imaging surface of the image sensor, when the reflected light is detected, and measures the time from the emission of the laser light to the light reception.

7. The three-dimensional sensing system according to claim 4, wherein
when the operation mode is the flash LiDAR operation mode, the driving unit executes the drive control of the photonic crystal laser array so that the laser light is simultaneously emitted to a specific region from a plurality of elements of the photonic crystal laser array.

8. The three-dimensional sensing system according to claim 7, wherein
the distance calculation unit measures the time from the emission to the light reception in each pixel of the image sensor, when the reflected light is detected.

9. The three-dimensional sensing system according to claim 4, wherein
when the operation mode is the light-section method operation mode, the driving unit executes the drive control of the photonic crystal laser array so as to irradiate the measuring object with stripe-shaped laser light generated by the photonic crystal laser array.

10. The three-dimensional sensing system according to claim 9, wherein
the distance calculation unit when the reflected light is detected, obtains a reflected light image as an imaging pattern, executes triangular ranging with the imaging pattern, calculates the distance to the measuring object, and obtains three-dimensional distance data for one line of the stripe-shaped light.

11. A three-dimensional sensing system comprising:
a signal transmitting unit comprising a two-dimensional photonic crystal surface emitting laser cell array configured to emit laser light to a measuring object;
a signal receiving unit comprising an optical system and an image sensor configured to receive reflected light emitted from the signal transmitting unit and reflected from the measuring object;
a control unit configured to control an operation mode of a light source of the laser light;
a transmission direction recognition unit configured to recognize an emitting direction of the laser light emitted from the two-dimensional photonic crystal surface emitting laser cell array;
a two-dimensional photonic crystal cell array driving unit configured to execute a drive control of the two-dimensional photonic crystal surface emitting laser cell array on the basis of the emitting direction of the laser light recognized by the transmission direction recognition unit, in accordance with the operation mode; and
a signal processing unit comprising a distance detection unit configured to calculate a distance to the measuring object on the basis of a light receiving position on an imaging surface of the image sensor and a time from light emission to light reception in accordance with the operation mode.

12. The three-dimensional sensing system according to claim 11, wherein
the signal transmitting unit further comprises a feedback photo diode array configured to execute a feedback control of the emitted laser light, wherein
the transmission direction recognition unit recognizes an emitting direction of the laser light emitted from the signal transmitting unit in accordance with feedback information provided from the feedback photo diode array.

13. The three-dimensional sensing system according to claim 12, wherein
the signal processing unit further comprises a reception direction recognition unit configured to recognize a reception direction of the reflected light on the basis of the light receiving position on the imaging surface of the image sensor, wherein
the two-dimensional photonic crystal cell array driving unit executes the drive control of the two-dimensional photonic crystal surface emitting laser cell array on the basis of the emitting direction of the laser light recognized by the transmission direction recognition unit and the reception direction of the reflected light recognized by the reception direction recognition unit.

14. The three-dimensional sensing system according to claim 11, wherein
the signal processing unit further comprises an object recognition logic configured to identify the measuring object on the basis of a calculation result of the distance detection unit.

15. The three-dimensional sensing system according to claim 11, further comprising
a main controlling unit configured to control the entire main system in which the three-dimensional sensing system is mounted.

16. The three-dimensional sensing system according to claim 15, wherein
the signal processing unit comprises a 3D image storage unit configured to store an image data captured by the image sensor, wherein
the three-dimensional sensing system further comprises an artificial intelligence unit configured to learn a sensing result of the three-dimensional sensing system on the basis of the image data stored and accumulated in the 3D image storage unit and to assists sensing processing executed by the three-dimensional sensing system.

17. The three-dimensional sensing system according to claim 15, further comprising
a user interface unit connected to the main controlling unit, wherein
the user interface unit comprises an input unit for a user to input an instruction to the three-dimensional sensing system, and an output unit for presenting the user sensing information detected by the three-dimensional sensing system.

18. The three-dimensional sensing system according to claim 11, wherein
the operation mode comprises a LiDAR operation mode, a flash LiDAR operation mode, and a light-section method operation mode.

19. A three-dimensional sensing system comprising:
a flash light source configured to emit laser light to an entire surface of a specific region;
a two-dimensional photonic crystal surface emitting laser cell array configured to emit the laser light to a target region of the specific region;
a control unit configured to control an operation mode of a laser light source;
a flash driving unit configured to execute a drive control of the flash light source and a two-dimensional photonic crystal cell array driving unit configured to execute a drive control of the two-dimensional photonic crystal surface emitting laser cell array, in accordance with the operation mode controlled by the control unit;
a signal receiving unit configured to receive a reflected light that is the laser light emitted from the flash light source and reflected from a measuring object included in the specific region, and to receive a reflected light that is the laser light emitted from the two-dimensional photonic crystal surface emitting laser cell array and reflected from measuring object included in the target region;
a signal processing unit configured to execute signal processing of the reflected light received the signal receiving unit in accordance with the operation mode; and
a distance detection unit configured to execute calculation processing of the distance to the measuring object with respect to the signal processed by the signal processing unit in accordance with the operation mode, wherein
the signal processing unit determines whether or not there is any region where the signal to noise ratio of the reflected light emitted from the flash light source and reflected is lower than the predetermined threshold value in the specific region, wherein
if there is a region where the signal to noise ratio is lower than the predetermined threshold value, the signal processing unit controls the two-dimensional photonic crystal cell array driving unit to irradiate only the region where the signal to noise ratio is lower than the predetermined threshold value as a target with spot laser light from the two-dimensional photonic crystal surface emitting laser cell array.

20. The three-dimensional sensing system according to claim 19, wherein
the signal processing unit determines whether or not there is any region where the signal to noise ratio of the reflected light that is emitted in spot from the two-dimensional photonic crystal surface emitting laser cell array and is reflected is lower than the predetermined threshold value,
if there is a region where the signal to noise ratio is lower than the predetermined threshold value, as a result of the determination, the signal processing unit controls the two-dimensional photonic crystal cell array driving unit to increase light intensity emitted from the two-dimensional photonic crystal surface emitting laser cell array and to irradiate only the region where the signal to noise ratio is lower than the predetermined threshold value as a target with spot laser light from the two-dimensional photonic crystal surface emitting laser cell array.
